(19) United States
(12) Patent Application Publication
(10) Pub. No.: US 2017/0069655 A1
(43) Pub. Date: Mar. 9, 2017

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventors: Daigo ICHINOSE, Nagoya (JP); Junichi HASHIMOTO, Yokkaichi (JP); Noriyuki ASAMI, Yokkaichi (JP)

(73) Assignee: Kabushiki Kaisha Toshiba, Minato-ku (JP)

(21) Appl. No.: 15/017,916

(22) Filed: Feb. 8, 2016

Related U.S. Application Data
(60) Provisional application No. 62/215,566, filed on Sep. 8, 2015.

(51) Int. Cl. H01L 27/115; H01L 21/311

(52) U.S. Cl. CPC H01L 27/11582; H01L 27/11556; H01L 21/31111

(57) ABSTRACT

According to one embodiment, a method for manufacturing a semiconductor memory device is disclosed. A trench is formed in a structure on a body. The structure includes first and second films alternately stacked in a first direction. A part of the first films is removed through the trench. One of the first films has a first side surface. Other one of the first films having a second side surface is positioned between the one of the first films and the body. The removing makes a distance between the trench and the second side surface shorter than a distance between the trench and the first side surface. A first space formed by the removing is filled with an insulating material. The first films are removed via a hole formed in the structure. A second space formed by the removing the first films is filled with a conductive material.

### CROSS-REFERENCE TO RELATED APPLICATIONS

This application is based upon and claims the benefit of priority from U.S. Provisional Patent Application 62/215,566, filed on Sep. 8, 2015; the entire contents of which are incorporated herein by reference.

### FIELD

Embodiments described later relate to a semiconductor memory device and a method for manufacturing the same.

### BACKGROUND

In the semiconductor memory device, there is desired an increase in memory capacity.

### BRIEF DESCRIPTION OF THE DRAWINGS

FIG. 1 is a schematic cross-sectional view illustrating a semiconductor memory device according to a first embodiment;

FIG. 2A through FIG. 2D are schematic cross-sectional views illustrating a method for manufacturing the semiconductor memory device according to the first embodiment;

FIG. 3A through FIG. 3C are schematic cross-sectional views illustrating the method for manufacturing the semiconductor memory device according to the first embodiment;

FIG. 4A through FIG. 4D are schematic cross-sectional views illustrating another method for manufacturing the semiconductor memory device according to the first embodiment;

FIG. 5A through FIG. 5D are schematic cross-sectional views illustrating another method for manufacturing the semiconductor memory device according to the first embodiment;

FIG. 6 is a schematic cross-sectional view illustrating another semiconductor memory device according to the first embodiment;

FIG. 7A through FIG. 7C are schematic cross-sectional views illustrating another method for manufacturing the semiconductor memory device according to the first embodiment;

FIG. 8 is a schematic cross-sectional view illustrating another semiconductor memory device according to the first embodiment;

FIG. 9 is a schematic cross-sectional view illustrating another semiconductor memory device according to the first embodiment;

FIG. 10A through FIG. 10C are schematic cross-sectional views illustrating another method for manufacturing the semiconductor memory device according to the first embodiment;

FIG. 11A through FIG. 11C are schematic cross-sectional views illustrating another method for manufacturing the semiconductor memory device according to the first embodiment;

FIG. 12 is a schematic cross-sectional view illustrating another semiconductor memory device according to the first embodiment;

FIG. 13A through FIG. 13D are schematic cross-sectional views illustrating another method for manufacturing the semiconductor memory device according to the first embodiment;

FIG. 14 is a schematic cross-sectional view illustrating a semiconductor memory device according to a second embodiment;

FIG. 15A through FIG. 15D are schematic cross-sectional views illustrating a method for manufacturing the semiconductor memory device according to the second embodiment;

FIG. 16A through FIG. 16C are schematic cross-sectional views illustrating a method for manufacturing the semiconductor memory device according to the second embodiment;

FIG. 17A through FIG. 17D are schematic cross-sectional views illustrating another method for manufacturing the semiconductor memory device according to the second embodiment;

FIG. 18A through FIG. 18D are schematic cross-sectional views illustrating another method for manufacturing the semiconductor memory device according to the second embodiment;

FIG. 19 is a schematic cross-sectional view illustrating another semiconductor memory device according to the second embodiment;

FIG. 20A through FIG. 20D are schematic cross-sectional views illustrating another method for manufacturing the semiconductor memory device according to the embodiment;

FIG. 21A through FIG. 21D are schematic cross-sectional views illustrating another method for manufacturing the semiconductor memory device according to the embodiment;

FIG. 22A through FIG. 22C are schematic cross-sectional views illustrating another method for manufacturing the semiconductor memory device according to the embodiment;

FIG. 23A and FIG. 23B are schematic cross-sectional views illustrating another method for manufacturing the semiconductor memory device according to the embodiment;

FIG. 24 is a schematic cross-sectional view illustrating another semiconductor memory device according to the embodiment;

FIG. 25A through FIG. 25C are schematic cross-sectional views illustrating another method for manufacturing the semiconductor memory device according to the embodiment;

FIG. 26A and FIG. 26B are schematic cross-sectional views illustrating another method for manufacturing the semiconductor memory device according to the embodiment;

FIG. 27 is a schematic cross-sectional view illustrating a semiconductor memory device according to the embodiment;

FIG. 28A and FIG. 28B are schematic cross-sectional views illustrating a part of the semiconductor memory device according to the embodiment; and

FIG. 29 is a schematic cross-sectional view illustrating a semiconductor memory device according to the embodiment.

### DETAILED DESCRIPTION

According to one embodiment, a method for manufacturing a semiconductor memory device is disclosed. The method can include forming a trench in a structure provided on a lower body. The structure includes a plurality of first films and a plurality of second films alternately stacked in a first direction crossing a surface of the lower body. The method further includes removing a part of the plurality of first films being exposed inside of the trench. One of the plurality of first films has a first side surface crossing a second direction perpendicular to the first direction. Other one of the plurality of first films is positioned between the one of the plurality of first films and the lower body. The other one of the plurality of first films has a second side surface crossing the second direction. The removing the part of the plurality of first films makes a second distance shorter than a first distance. The first distance is between the trench and the first side surface in the second direction. The second distance is between the trench and the second side surface in the second direction. The method further includes filling a first space formed by the removing the part of each of the plurality of first films with an insulating material. The method further includes forming a hole in the structure after the filling with the insulating material, and removing the plurality of first films via the hole. The method further includes filling a second space formed by the removing the first films with a conductive material to form a plurality of conductive films arranged in the first direction.

Various embodiments will be described hereinafter with reference to the accompanying drawings.

The drawings are schematic and conceptual, and the relationships between the thickness and width of portions, the size ratio among portions, etc., are not necessarily the same as the actual values thereof. Further, the dimensions and proportions may be illustrated differently among drawings, even for identical portions.

In the present specification and drawings, the same elements as those described previously with reference to earlier figures are labeled with like reference numerals, and the detailed description thereof is omitted as appropriate.

### First Embodiment

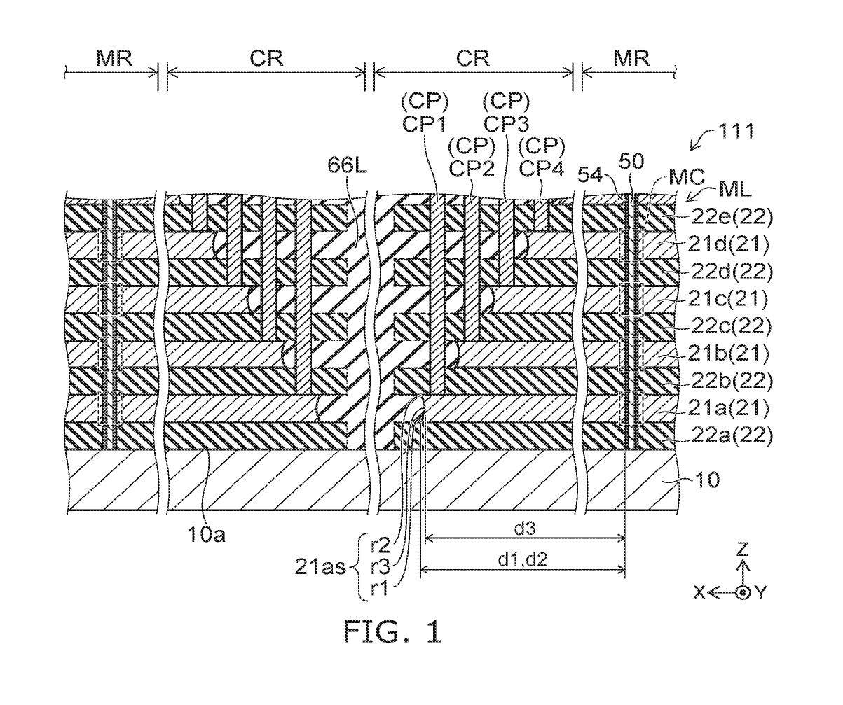

FIG. 1 is a schematic cross-sectional view illustrating a semiconductor memory device according to a first embodiment.

As shown in FIG. 1, the semiconductor memory device 111 according to the embodiment includes a stacked body ML, semiconductor pillars 50, and memory films 54.

The stacked body ML includes a plurality of conductive layers 21 and a plurality of insulating layers 22 which are alternately stacked.

The stacking direction (a first direction) of the conductive layers 21 and the insulating layers 22 is defined as a Z-axis direction. One of directions perpendicular to the Z-axis direction is defined as an X-axis direction. The direction perpendicular to the Z-axis direction and the X-axis direction is defined as a Y-axis direction.

The stacked body ML is provided on a surface 10u (e.g., an upper surface) of a lower body 10. The lower body 10 can also be a substrate. The lower body 10 can also be a layer (e.g., an insulating layer) provided on a substrate. The lower body 10 may be a conductive layer. The lower body 10 may include a conductive layer. The surface 10u of the lower body 10 extends along, for example, an X-Y plane. The first direction crosses the surface 10u. The first direction is substantially perpendicular to the surface 10u.

For example, the plurality of conductive layers 21 include a first conductive layer 21a, a second conductive layer 21b, a third conductive layer 21c, a fourth conductive layer 21d, and so on.

These conductive layers are arranged along the Z-axis direction in this order. These conductive layers are separated from each other in the Z-axis direction.

For example, the plurality of insulating layers 22 include a first insulating layer 22a, a second insulating layer 22b, a third insulating layer 22c, a fourth insulating layer 22d, a fifth insulating layer 22e, and so on. These insulating layers are arranged along the Z-axis direction in this order. These insulating layers are separated from each other in the Z-axis direction.

The semiconductor pillars 50 each extends in the first direction through the stacked body ML.

The memory film 54 is provided between the semiconductor pillar 50 and the stacked body ML. The memory film 54 includes, for example, a charge storage film, and the like. An example of the memory film 54 will be described later.

Memory cells MC are formed between the plurality of conductive layers 21 and the semiconductor pillar 50.

On the lower body 10, an area provided with the memory cells MC corresponds to a memory region MR. On the lower body 10, there is further provided a connection region CR. The plurality of conductive layers 21 extend from the memory region MR to the connection region CR. In the connection region CR, a plurality of connection sections CP (e.g., first through fourth connection sections CP1 through CP4) are provided. The plurality of connection sections CP extend along the first direction. One of the plurality of connection sections CP is electrically connected to one of the plurality of conductive layers 21.

In the embodiment, the state in which a first conductor is electrically connected to a second conductor includes the state in which the first conductor and the second conductor have physical contact with each other. The state in which the first conductor is electrically connected to the second conductor includes the state in which a third conductor (including a semiconductor) is inserted between the first conductor and the second conductor and a current flows between the first conductor and the second conductor via the third conductor. It is also possible to provide a plurality of third conductors in a current path between the first conductor and the second conductor.

The plurality of conductive layers 21 form, for example, word lines. At least a part of the semiconductor pillar 50 forms, for example, a channel. In addition, a bit line, a source line, and on the like are provided. An example of these interconnections will be described later.

In this example, two connection regions CR are provided between two memory regions MR.

In the connection regions CR, the positions of end portions of the plurality of conductive layers 21 vary to form a stepped shape. In other words, the distances between the end portions of the plurality of conductive layers 21 and the memory films 54 descend as the distance from the lower body 10 increases. By causing the shape of the plurality of conductive layers 21 to have the stepped shape, connection with the connection sections CP becomes easy. On the part having the stepped shape, there is provided an insulating section 66L.

In this example, a central portion in the thickness direction (the first direction) of the end surface of each of the plurality of conductive layers 21 in the connection region CR recedes from ends in the thickness direction thereof as shown in FIG. 1. In other words, in one end surface of the conductive layer 21, the ends in the thickness direction project from the central portion in the thickness direction.

Hereinafter, the configuration will be described.

As described above, the stacked body ML includes the first insulating layer 22a, the second insulating layer 22b, and the first conductive layer 21a. The second insulating layer 22b is separated from the first insulating layer 22a in the first direction. The first conductive layer 21a is provided between the first insulating layer 22a and the second insulating layer 22b.

The first conductive layer 21a includes an end surface 21as. The end surface 21as is separated from the memory film 54 in a second direction (the X-axis direction in this example) crossing the first direction. The end surface 21as crosses the second direction. The end surface 21as includes first through third regions r1 through r3. The first region r1 is located on the first insulating layer 22a side. The second region r2 is located on the second insulating layer 22b side.

In other words, the position in the first direction (the Z-axis direction) of the first region r1 is located between the position in the first direction of the third region r3 and the position in the first direction of the first insulating layer 22a. The position in the first direction of the second region r2 is located between the position in the first direction of the third region r3 and the position in the first direction of the second insulating layer 22b.

A third distance d3 along a second direction (the X-axis direction) between the third region r3 and the memory film 54 is shorter than a first distance d1 along the second direction between the first region r1 and the memory film 54. In other words, the third region r3 (the central portion of the first conductive layer 21a) recedes from the first region r1.

In the example, in addition, the third distance d3 is shorter than a second distance d2 along the second direction between the second region r2 and the memory film 54.

Due to such a configuration, the contact area between the first conductive layer 21a and the first insulating layer 22a increases, for example. There exists a reference example in which, for example, the third distance d3 is equal to the first distance d1, and at the same time, is equal to the second distance d2. In the case in which the third distance d3 is equal between the configuration illustrated in FIG. 1 and the reference example, the contact area between the first conductive layer 21a and the first insulating layer 22a becomes larger in the configuration illustrated in FIG. 1 compared to the reference example. Thus, for example, the adhesiveness between the conductive layers and the insulating layers, for example, is improved. Stable connection can be obtained. For example, the area of the connection regions CR can be reduced. Therefore, for example, the area of the memory region MR can be enlarged. Thus, the memory capacity can be increased.

Hereinafter, an example of a method for manufacturing a semiconductor memory device 111 will be described.

(First Manufacturing Method)

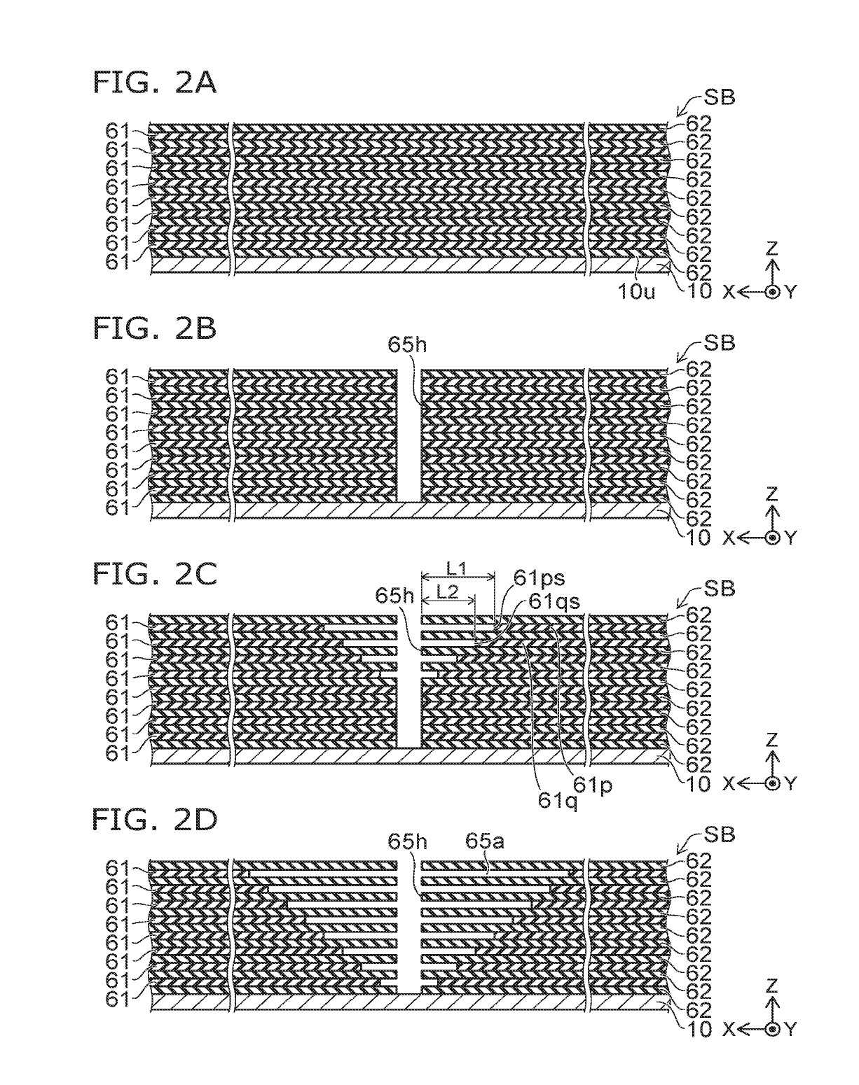

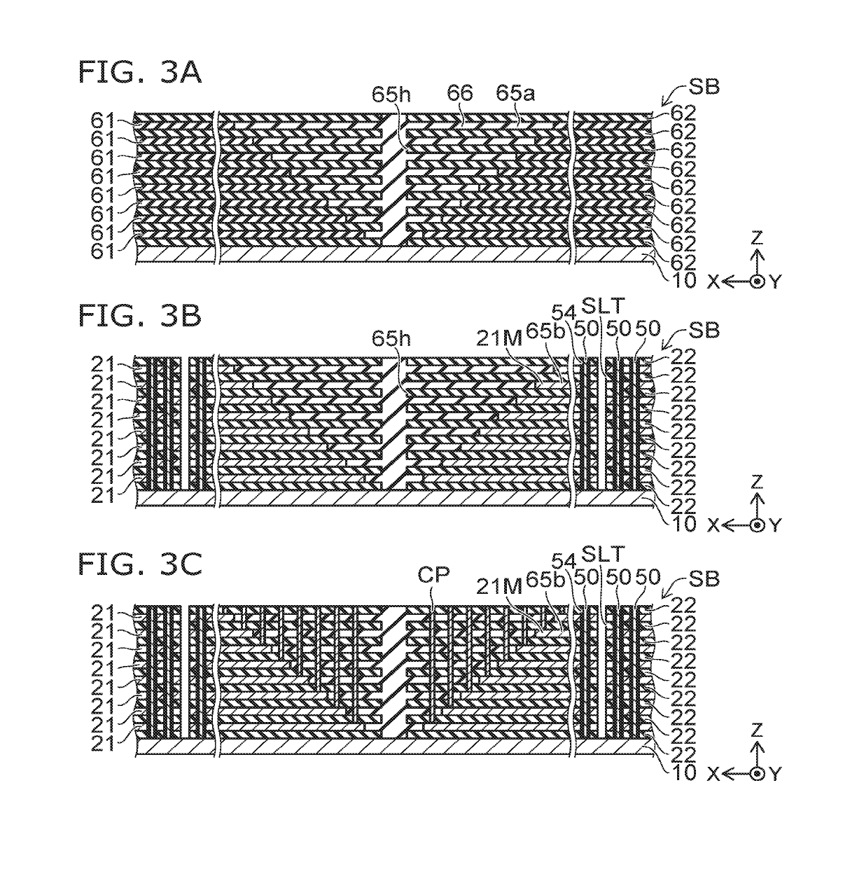

FIG. 2A through FIG. 2D and FIG. 3A through FIG. 3C are schematic cross-sectional views illustrating a method for manufacturing the semiconductor memory device according to the first embodiment.

As shown in FIG. 2A, a structure SB is formed on the lower body 10. The structure SB is provided on the surface 10u of the lower body 10. The structure SB includes a plurality of first films 61 and a plurality of second films 62 alternately stacked in the first direction. The first direction crosses the surface 10u of the lower body 10. The first direction is substantially perpendicular to the surface 10u. The first films 61 each includes, for example, silicon nitride. The second films 62 each includes, for example, silicon oxide.

As shown in FIG. 2B, a trench 65h is formed in the structure SB. On the inner side of the trench 65h of the structure SB, the plurality of first films 61 and the plurality of second films 62 are exposed.

As shown in FIG. 2C, a part of each of the plurality of first films 61 exposed on the inner side of the trench 65h is removed. The process of removing a part of each of the plurality of first films 61 includes removing a part of each of the first films 61 using wet etching. In the case in which the first films 61 each includes silicon nitride, a phosphoric acid solution, for example, is used as an etchant. Etching is performed using the etchant supplied from an opening section of the trench 65h.

On this occasion, as shown in FIG. 2C, the degree of removing the first film 61 in a part near to an upper side (the opening section) of the trench 65h is higher than the degree of removing the first film 61 in a lower side part of the trench 65h. The receding amount of the first film 61 in the part near to the upper side of the trench 65h is greater than the receding amount of the first film 61 in the lower side part of the trench 65h. For example, in the part near to the opening section, the concentration of the component causing a contribution to etching in the etchant is higher than that in the part far from the opening section. Thus, such a difference in etching amount can be obtained.

For example, one (the first film 61p) of the plurality of first films 61 has a first side surface 61pa crossing the second direction (the X-axis direction) perpendicular to the first direction. Another (the first film 61q) of the plurality of first films 61 is located between the one (the first film 61p) thereof and the lower body 10. Another (the first film 61q) thereof has a second side surface 61qs crossing the second direction. A second distance L2 along the second direction between the trench 65h and the second side surface 61qs is shorter than a first distance L1 along the second direction between the trench 65h and the first side surface 61pa.

As described above, in the method, removing a part of each of the plurality of first films 61 is performed. The positions of the end portions of the plurality of first films 61 vary to form a stepped shape.

As shown in FIG. 2D, etching is further continued. Thus, the positions of the end portions of the plurality of first films 61 form a predetermined stepped shape. Thus, a space (a first space 65a) is formed in an area from which a part of each of the plurality of first films 61 is removed.

As shown in FIG. 3A, the first space 65a (the space formed by the removing a part of each of the plurality of first films 61) is filled with an insulating material 66. The insulating material 66 is, for example, silicon oxide. The trench 65h is also filled with the insulating material 66. The insulating film 66 forms an insulating section 66L.

As shown in FIG. 3B, the semiconductor pillars 50 penetrating the structure SB are formed. In this process, for example, memory holes each piercing the structure SB in the first direction are formed, and then the memory film 54 is formed on an inner wall surface of each of the memory holes. Then, after forming the memory films 54, the semiconductor pillar 50 extending in the first direction is formed in the remaining space of the memory hole. In such a manner as described above, the semiconductor pillars 50 are formed.

After forming the semiconductor pillars 50 (i.e., after the process of filling the space with the insulating material 66), a hole SLT is formed in the structure SB. The hole SLT can also be a trench. The hole SLT can also be a slit. The plurality of first films 61 are removed via the hole SLT.

Further, a second space 65b formed by the removing the first films 61 is filled with a conductive material 21M. Thus, the plurality of conductive layers 21 arranged in the first direction are formed from the conductive material 21M. The second films 62 respectively form the insulating layers 22. As the conductive material 21M, there is used, for example, tungsten. In the embodiment, the conductive material 21M is arbitrary.

As shown in FIG. 3C, the second films 62 (the insulating layers 22) and the insulating material 66 are partially removed to form contact holes. The contact holes reach the plurality of conductive layers 21, and each extends in the first direction. The contact holes are filled with a conductive material. Thus, the connection sections CP are formed.

In the first manufacturing method described above, when the plurality of first films 61 are etched via the trench 65h, there is used the fact that the etching rate differs along the height direction (the first direction). The difference in the etching rate is caused by a difference in concentration of the component causing a contribution to etching in the etchant between, for example, an area near to the opening section of the trench 65h and a deep area of the trench 65h.

For example, the etchant is used in the process of removing a part of each of the plurality of first films 61. The etching rate of the one (the first film 61p) of the plurality of first films 61 with respect to the etchant is higher (faster) than the etching rate of the other one (the first film 61q) of the plurality of first films 61. The plurality of plurality of first films 61 are processed to have the stepped shape using such a difference in etching rate.

Thus, for example, the process becomes simple. For example, a variation in processing is suppressed. For example, the accuracy of the positions of the end portions of the first films 61 can be improved. Thus, the connection regions CR can be narrowed. Thus, the semiconductor memory device with a high memory capacity can be manufactured.

In contrast, there exists a reference example of forming a mask on the structure SB including the plurality of first films 61 and the plurality of second films 62 stacked alternately, and then alternately repeating processing of the structure SB via the mask and slimming of the mask. In this reference example, the number of processes is large. Further, in some cases, the accuracy of the positions of the end portions of the plurality of first films 61 is not sufficient due to the variation in processing.

In the first manufacturing method according to the embodiment, the number of processes can be reduced. Further, the variation in processing is suppressed, and thus, high positional accuracy can be obtained.

(Second Manufacturing Method)

The semiconductor memory device 111 described above can also be manufactured using a second manufacturing method described below.

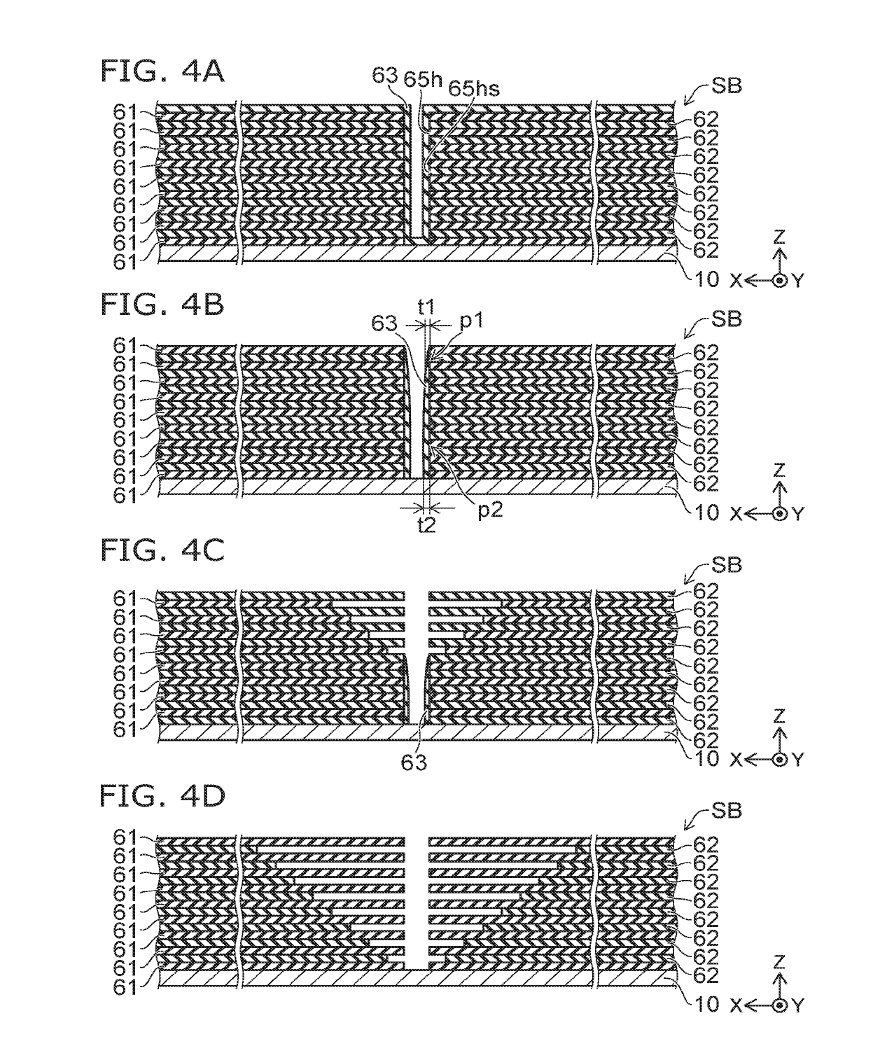

FIG. 4A through FIG. 4D are schematic cross-sectional views illustrating another method of manufacturing the semiconductor memory device according to the first embodiment.

Also in this example, there is provided the structure SB on the lower body 10. In the second manufacturing method, the following process is performed between the process (see FIG. 2B) of forming the trench 65h and the process (see FIG. 2C) of removing a part of each of the plurality of first films 61.

As shown in FIG. 4A, a third film 63 is formed on a sidewall 65hs of the trench 65h of the structure SB. The third film 63 can also be formed on an upper surface of the structure SB. The third film 63 includes, for example, substantially the same material as that of the first films 61. The third film 63 includes, for example, silicon nitride. The third film 63 is formed using, for example, an atomic layer deposition (ALD) method.

As shown in FIG. 4B, the third film 63 is processed. This processing is performed between the process (FIG. 3A) of forming the third film and the process (FIG. 2C) of removing a part of each of the plurality of first films 61. In the processing of the third film 63, a length t1 (the thickness) along the second direction (the X-axis direction) of the third film 63 at a first position p1 distant from the lower body 10 is made shorter than a length t2 (the thickness) along the second direction of the third film 63 at a second position p2 located between the first position p1 and the lower body 10.

For example, the etching rate of the third film 63 in the part near to the opening section of the trench 65h is higher (faster) than the etching rate of the third film 63 deep in the trench 65h. Thus, the slimming described above (a variation in length, a variation in thickness) is achieved.

As shown in FIG. 4C, in the case of continuing the removal (etching) of the third film 63, a part of each of the plurality of first films 61 (in a part corresponding to an upper layer area) is exposed in the part from which the third film 63 has been removed. The part of each of the first films 61 is removed at the same time as the removing the third film 63.

Specifically, the process of removing a part of each of the plurality of first films 61 includes a process of removing the part corresponding to the first position p1 of the third film 63, and then removing at least a part of one of the plurality of first films 61, which has been exposed by the removing the part corresponding to the first position p1. Further, the process of removing a part of each of the plurality of first films 61 includes a process of removing the part corresponding to the second position p2 of the third film 63 after the removing the part corresponding to the first position p1, and then removing at least a part of another of the plurality of first films 61, which has been exposed by the removing the part corresponding to the second position p2. As described above, the third film 63 is gradually removed along the first direction, and a part of each of the first films 61 having been exposed by the removal is removed in sequence.

In this example, the thickness along the second direction of the third film 63 is varied, and the third film 63 is gradually removed along the first direction. Thus, the timing of starting the removal (etching) of a part of each of the plurality of first films 61 is controlled. The time of starting the removal (etching) of a part of each of the plurality of first films 61 varies along the first direction.

Thus, as shown in FIG. 4D, the end portions of the plurality of first films 61 are processed to form the stepped shape. Subsequently, by performing, for example, the process described with reference to FIG. 3A through FIG. 3C, the semiconductor memory device 111 can be formed.

Also in the second manufacturing method, the number of processes can be reduced. Further, the variation in processing is suppressed, and thus, high positional accuracy can be obtained. In the second manufacturing method, slimming of the third film 63 is performed. By using the third film 63, the variation in processing of the plurality of plurality of first films 61 can be suppressed. Thus, higher accuracy can be obtained.

(Third Manufacturing Method)

The semiconductor memory device 111 described above can also be manufactured using a third manufacturing method described below.

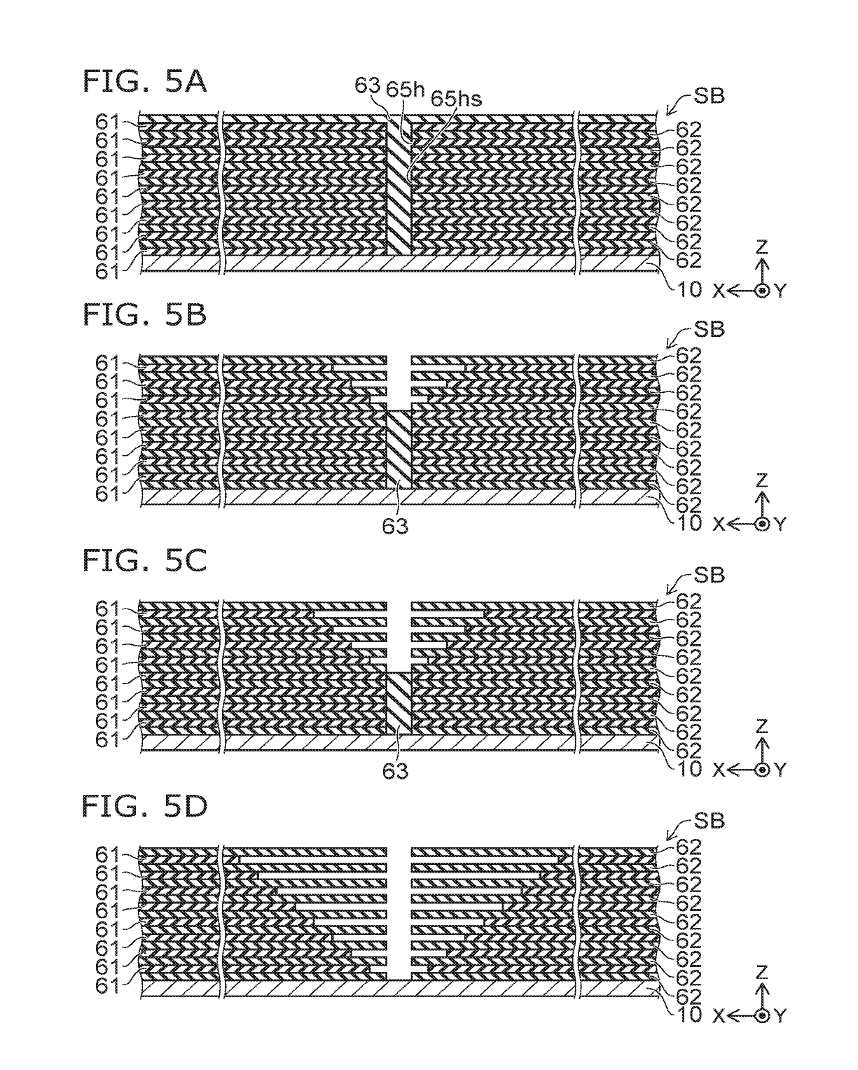

FIG. 5A through FIG. 5D are schematic cross-sectional views illustrating another method of manufacturing the semiconductor memory device according to the first embodiment.

Also in this example, there is provided the structure SB on the lower body 10. In the third manufacturing method, the following process is performed between the process (see FIG. 2B) of forming the trench 65h and the process (see FIG. 2C) of removing a part of each of the plurality of first films 61.

As shown in FIG. 5A, the third film 63 is formed in the trench 65h. The third film 63 can also be formed on the upper surface of the structure SB. The third film 63 includes, for example, substantially the same material as that of the first films 61. The third film 63 includes, for example, silicon nitride.

As shown in FIG. 5B, a part of the third film 63 is removed by etching, and then a part of each of the first films 61, which have been exposed by the removing a part of the third film 63, is removed by etching.

Further, as shown in FIG. 5C, the third film 63 is further removed by etching. Thus, another part of the plurality of first films 61 is exposed. By the etching of the third film 63, the removing the first films 61 having been newly exposed is started.

Specifically, in the process of removing a part of each of the plurality of first films 61, a part of the third film 63 is removed to cause the third film 63 to recede along the first direction. A process of removing at least a part of one of the plurality of first films 61 having been exposed by the recession of the third film 63 is included. Further, the process of removing a part of each of the plurality of first films 61 further includes a process of causing the third film 63 to further recede after the recession of the third film 63 described above, and then removing at least a part of another of the plurality of first films 61, which has been exposed by the further recession of the third film 63.

In this example, the third film 63 is gradually removed along the first direction. Thus, the timing of starting the removal (etching) of a part of each of the plurality of first films 61 is controlled. The time of starting the removal (etching) of a part of each of the plurality of first films 61 varies along the first direction.

Thus, as shown in FIG. 5D, the end portions of the plurality of first films 61 are processed to form the stepped shape. Subsequently, by performing, for example, the process described with reference to FIG. 3A through FIG. 3C, the semiconductor memory device 111 can be formed.

Also in the third manufacturing method, the number of processes can be reduced. Further, the variation in processing is suppressed, and thus, high positional accuracy can be obtained. In the third manufacturing method, the third film 63 is provided, and the third film 63 is made to recede in sequence to expose the plurality of first films 61 in sequence. Thus, the variation in processing of the plurality of first films 61 can be suppressed. Thus, higher accuracy can be achieved.

The speed of the recession along the first direction of the third film 63 has an influence on the speed of the sequential exposure of the plurality of first films 61. In the case in which the length in the second direction of the third film 63 is excessively short, the space existing after the third film 63 is removed becomes excessively narrow, and the etching time for the first films 61 becomes excessively long, for example. If the length in the second direction of the third film 63 is excessively long, the variation in recession amount between the plurality of first films 61 becomes large, for example.

(Another Semiconductor Memory Device According to First Embodiment)

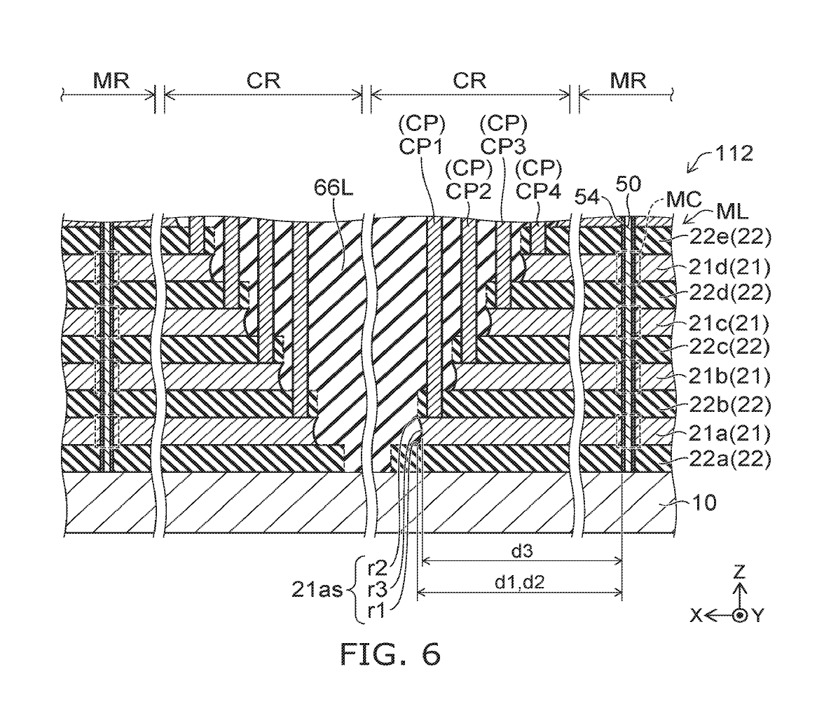

FIG. 6 is a schematic cross-sectional view illustrating another semiconductor memory device according to the first embodiment.

As shown in FIG. 6, a semiconductor memory device 112 according to the embodiment also includes the stacked body ML, the semiconductor pillars 50, and the memory films 54. In the semiconductor memory device 112, in the connection regions CR, the positions (the positions in the X-axis direction) of the plurality of end portions of the insulating layers 22 follow the positions (the positions in the X-axis direction) of the end portions of the conductive layers 21 provided on the lower side (the lower body 10 side) of the plurality of insulating layers 22. The rest of the configuration is substantially the same as the configuration of the semiconductor memory device 111, and therefore, the description thereof will be omitted. The configuration of the semiconductor memory device 112 is formed using, for example, a fourth manufacturing method described below.

(Fourth Manufacturing Method)

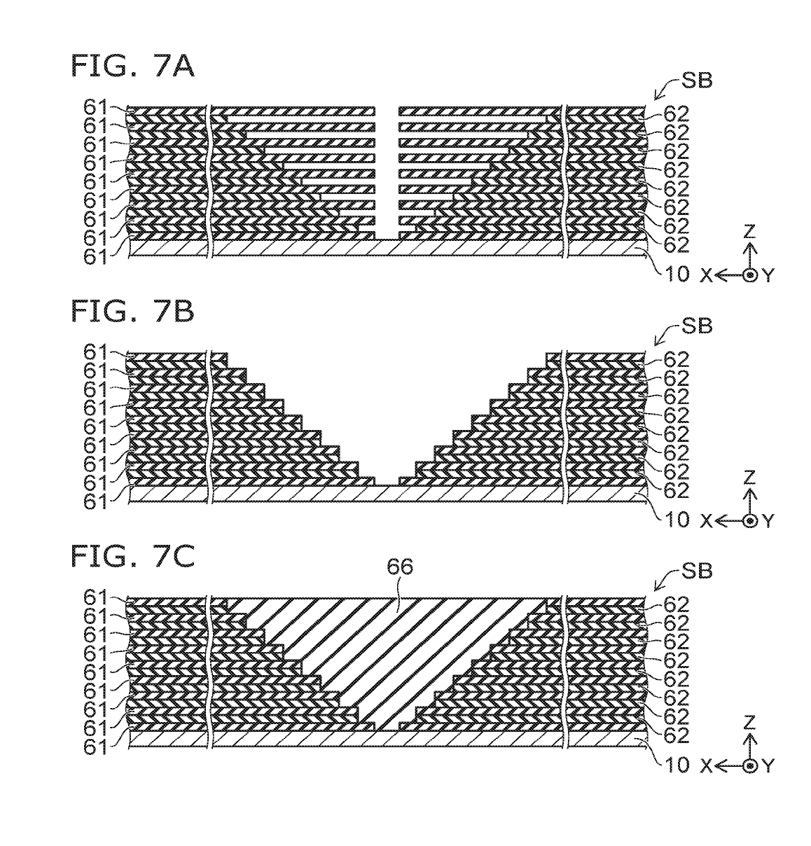

FIG. 7A through FIG. 7C are schematic cross-sectional views illustrating another method of manufacturing the semiconductor memory device according to the first embodiment.

As shown in FIG. 7A, the end portions of the plurality of first films 61 are processed to form the stepped shape. This configuration is the configuration described with reference to FIG. 2D. This configuration can be formed using, for example, either of the first through third manufacturing methods.

In the fourth manufacturing method, the following process is performed between the process (see FIG. 2B or FIG. 7A) of removing a part of each of the plurality of first films 61 and the process (see FIG. 3A) of filling the space with the insulating material 66.

As shown in FIG. 7B, a part of each of the plurality of second films 62 is removed. The part of each of the plurality of second films 62 is a part, which is not sandwiched by the plurality of first films 61 in the first direction (the Z-axis direction). On this part (the part not sandwiched by the plurality of first films 61 in the first direction) of the second film 62, the plurality of first films 61 are not provided. This part of the second film 62 is not covered with either of the plurality of first films 61. Such a part of each of the second films 62 is removed. In this removal, reactive ion etching (RIE), for example, is used. For example, anisotropic etching is performed.

Thus, the positions (the positions in the X-axis direction) of the respective end portions of the plurality of second films 62 substantially coincide with the positions (the positions in the X-axis direction) of the end portions of the first films 61 provided on the lower side (the lower body 10 side) of the plurality of second films 62.

As shown in FIG. 7C, the space thus formed is filled with the insulating material 66. Therefore, the process (see FIG. 3A or FIG. 7C) of filling the space with the insulating material 66 includes further filling the space, which has been formed by the removing the part (the part not sandwiched by the plurality of first films 61 in the first direction) described above of the second film 62, with the insulating material 66.

As described above, in the fourth manufacturing method, a part (a midair part) of each of the second films 62 is removed after the process of removing a part of each of the plurality of first films 61. The midair parts are parts of the second films 62, which have become in the state of being separated from each other in the midair by the removing a part of each of the first films 61. By removing the midair part of each of the second films 62, the second films 62 can be inhibited from being broken at unwanted parts. Thus, more stable processing can be achieved.

Also in the fourth manufacturing method, the number of processes can be reduced. Further, the variation in processing is suppressed, and thus, high positional accuracy can be obtained. In the fourth manufacturing method, the midair part of each of the second films 62 is removed. Thus, for example, the accuracy of the second films 62 and the first films 61 is improved. The second films 62 can be inhibited from being broken at unwanted positions. For example, foreign matters can be inhibited from being generated. For example, the yield ratio can be improved.

(Another Semiconductor Memory Device According to First Embodiment)

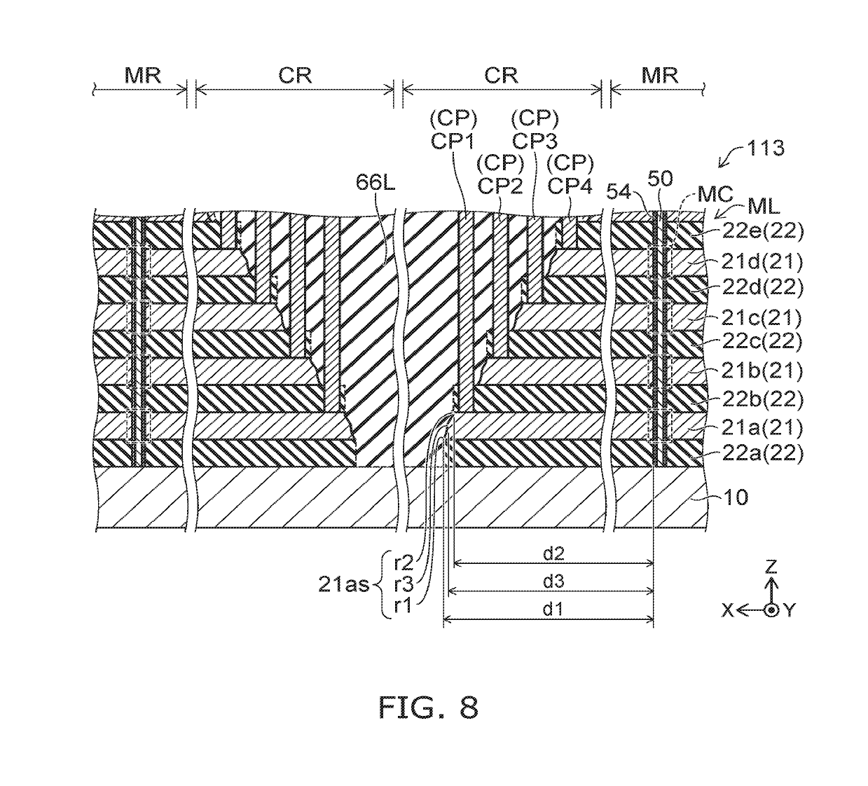

FIG. 8 is a schematic cross-sectional view illustrating another semiconductor memory device according to the first embodiment.

As shown in FIG. 8, a semiconductor memory device 113 according to the embodiment also includes the stacked body ML, the semiconductor pillars 50, and the memory films 54. In the semiconductor memory device 113, the shape of the end portion of the first conductive layer 21a is different from that of the semiconductor memory device 111. The rest of the configuration is substantially the same as the configuration of the semiconductor memory device 111, and therefore, the description thereof will be omitted.

In the semiconductor memory device 113, an end surface 21as (a surface crossing the second direction) of the first conductive layer 21a includes the first through third regions r1 through r3. The position in the first direction (the Z-axis direction) of the first region r1 is located between the position in the first direction of the third region r3 and the position in the first direction of the first insulating layer 22a. The position in the first direction of the second region r2 is located between the position in the first direction of the third region r3 and the position in the first direction of the second insulating layer 22b.

Also in this example, the third distance d3 along a second direction (the X-axis direction) between the third region r3 and the memory film 54 is shorter than the first distance d1 along the second direction between the first region r1 and the memory film 54. In other words, the third region r3 (the central portion of the first conductive layer 21a) recedes from the first region r1.

Further, in the semiconductor memory device 113, the third distance d3 is longer than the second distance d2 along the second direction between the second region r2 and the memory film 54. On this occasion, between the second insulating layer 22b and the lower body 10, there is disposed the first insulating layer 22a. In other words, the first region r1 in the end surface 21as of the first conductive layer 21a is located on the lower body 10 side (the lower side), and the second region r2 is located on the upper side. In such a configuration, the distance between the end surface 21as and the memory film 54 decreases along a direction from the bottom toward the top. In other words, the third distance d3 is shorter than the first distance d1, and the second distance d2 is shorter than the third distance d3. In other words, the end surface 21as is tilted. The end surface 21as has a positive tapered shape.

Such a configuration is formed using, for example, the fourth manufacturing method described above.

In other words, in the process (removing a part of each of the plurality of second films 62) described with reference to FIG. 7B described above, for example, a part of the first film 61 adjacent to the second film 62 is removed together with the second film 62. Thus, in the end portion of the first film 61, the position of the upper part recedes from the position of the lower part in some cases. In these cases, the configuration described above with respect to the semiconductor memory device 113 can be obtained.

In the semiconductor memory device 113, since the end surface 21as of the first conductive layer 21a has the positive tapered shape, breakage in the end portion of the first conductive layer 21a is suppressed. Thus, high positional accuracy can be obtained. Foreign matters are inhibited from being generated, and the yield ratio is improved.

(Another Semiconductor Memory Device According to First Embodiment)

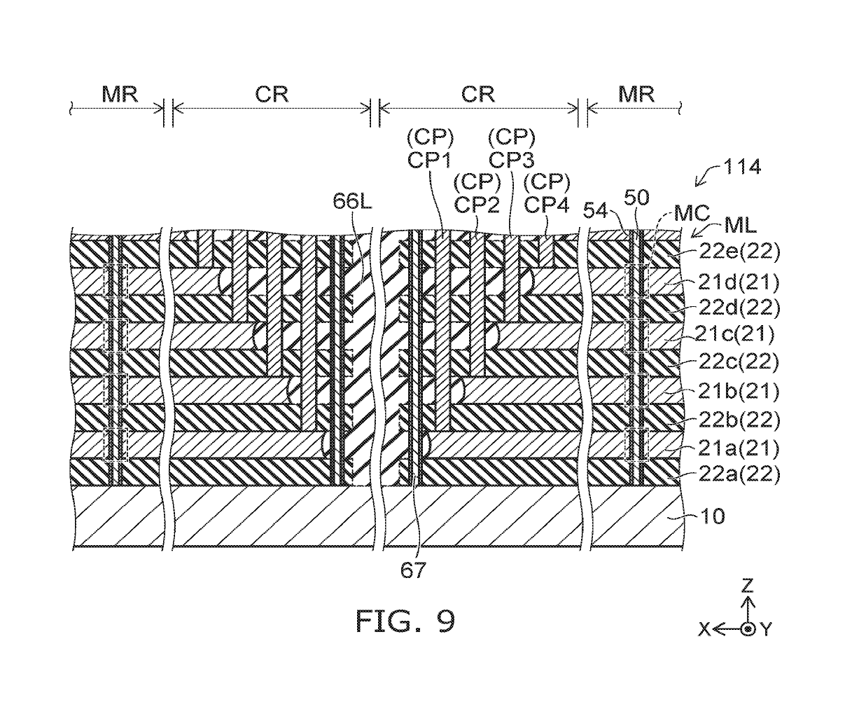

FIG. 9 is a schematic cross-sectional view illustrating another semiconductor memory device according to the first embodiment.

As shown in FIG. 9, a semiconductor memory device 114 according to the embodiment also includes the stacked body ML, the semiconductor pillars 50, and the memory films 54. In the semiconductor memory device 114, pillar sections 67 each extending in the first direction are further provided in the connection regions CR. In this example, the pillar sections 67 each supports the plurality of insulating layers 22 (the plurality of second films 62) during the process. The rest of the configuration is substantially the same as the configuration of the semiconductor memory device 111, and therefore, the description thereof will be omitted. The semiconductor memory device 114 is formed using, for example, a fifth manufacturing method described below.

(Fifth Manufacturing Method)

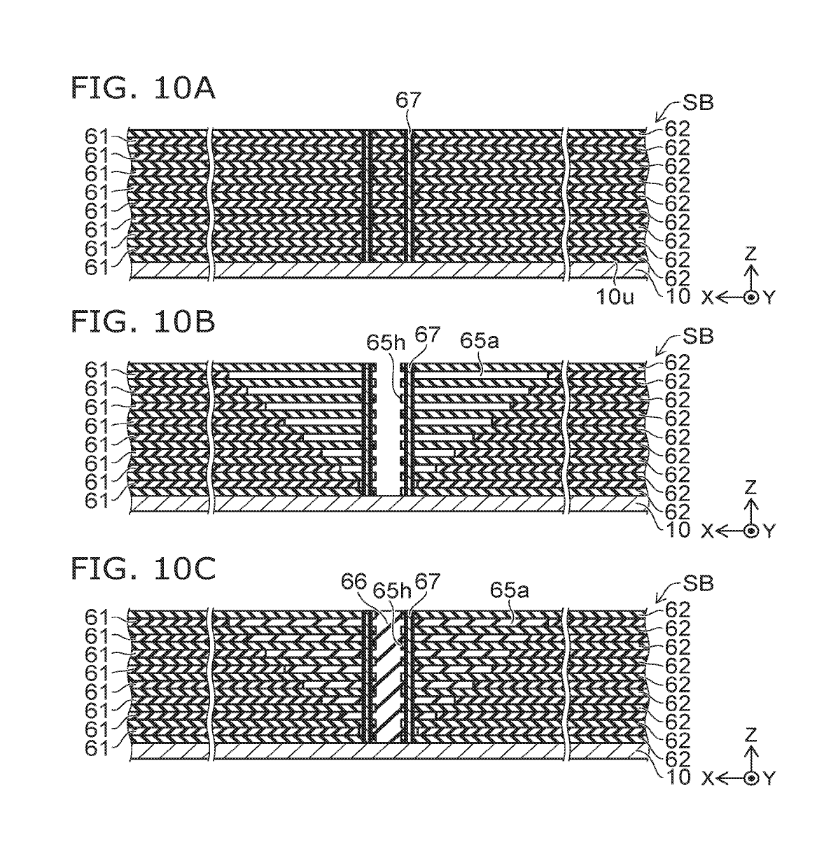

FIG. 10A through FIG. 10C are schematic cross-sectional views illustrating another method of manufacturing the semiconductor memory device according to the first embodiment.

As shown in FIG. 10A, the fifth manufacturing method further includes a process of forming the pillar sections 67 each piercing the structure SB in the first direction. This process is performed before, for example, the process (see, e.g., FIG. 2B) of forming the trench 65h in the structure SB. The trench 65h is formed so as to be separated from the pillar sections 67.

The pillar sections 67 are each formed by forming a hole extending in the first direction in the structure SB, and then forming a stacked film of, for example, a silicon oxide film and a silicon nitride film in the hole. As described later, it is also possible to perform at least a part of the formation of the pillar sections 67 at the same time as at least a part of the formation of the memory films 54.

As shown in FIG. 10B, a part of each of the plurality of first films 61 is removed. A part having a stepped shape is formed in the end portions of the plurality of first films 61. In this process, the process described with respect to the first through third manufacturing methods, for example, is performed.

As shown in FIG. 10B, by the removing a part of each of the plurality of first films 61, parts of the plurality of second films 62 become in the state of being separated from each other in the midair. In other words, the midair part of each of the second films 62 is formed. The midair part is held by the pillar sections 67. Thus, the midair part can be inhibited from being broken.

As shown in FIG. 10C, the first space 65a, which has been formed by removing a part of each of the plurality of first films 61, is filled with the insulating material 66. Subsequently, the processes described with respect to FIG. 3B and FIG. 3C are performed to form the semiconductor memory device 114.

(Sixth Manufacturing Method)

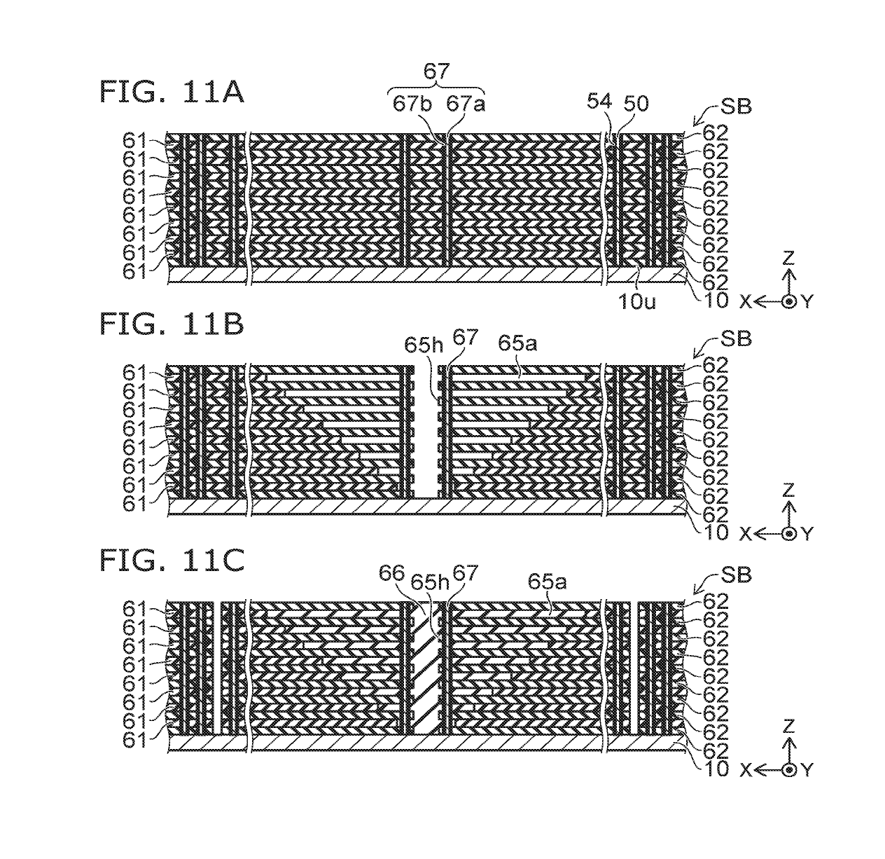

FIG. 11A through FIG. 11C are schematic cross-sectional views illustrating another method of manufacturing the semiconductor memory device according to the first embodiment.

As shown in FIG. 11A, the semiconductor pillars 50 and the memory films 54 extending in the first direction are provided to the structure SB. The memory film 54 is provided between the semiconductor pillar 50 and the structure SB. Meanwhile, the pillar sections 67 each piercing the structure SB in the first direction is provided. The pillar sections 67 each includes, for example, a core section 67a extending in the first direction, and an intermediate section 67b provided between the core section 67a and the structure SB. The core section 67a includes, for example, the same material as the material included in the semiconductor pillar 50. The intermediate section 67b includes, for example, at least a part of the material included in the memory film 54. The forming the pillar sections 67 can also be performed at the same time as, for example, the formation of the memory films 54 and the semiconductor pillars 50. For example, the intermediate section 67b can also include a stacked film of a film including silicon nitride and a film including silicon oxide.

As shown in FIG. 11B, a part of each of the plurality of first films 61 is removed. A part having a stepped shape is formed in the end portions of the plurality of first films 61. In this process, the process described with respect to the first through third manufacturing methods, for example, is performed.

Also in this case, by the removing a part of each of the plurality of first films 61, parts of the plurality of second films 62 become in the state of being separated from each other in the midair. The midair part of each of the second films 62 is formed. The midair part is held by the pillar sections 67. Thus, the midair part can be inhibited from being broken.

As shown in FIG. 11C, the first space 65a, which has been formed by removing a part of each of the plurality of first films 61, is filled with the insulating material 66.

Subsequently, the process described with respect to FIG. 3C is performed to form the semiconductor memory device 114.

(Another Semiconductor Memory Device According to First Embodiment)

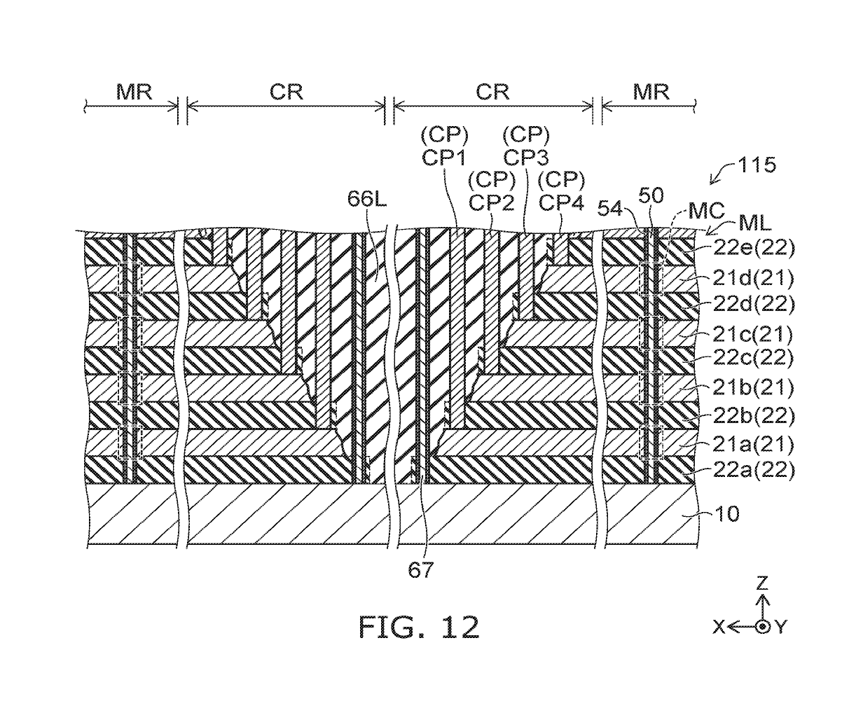

FIG. 12 is a schematic cross-sectional view illustrating another semiconductor memory device according to the first embodiment.

As shown in FIG. 12, in a semiconductor memory device 115 according to the embodiment, there are also provided the pillar sections 67. The rest of the configuration is substantially the same as the configuration of the semiconductor memory device 113, and therefore, the description thereof will be omitted. The semiconductor memory device 115 is formed using, for example, a seventh manufacturing method described below.

(Seventh Manufacturing Method)

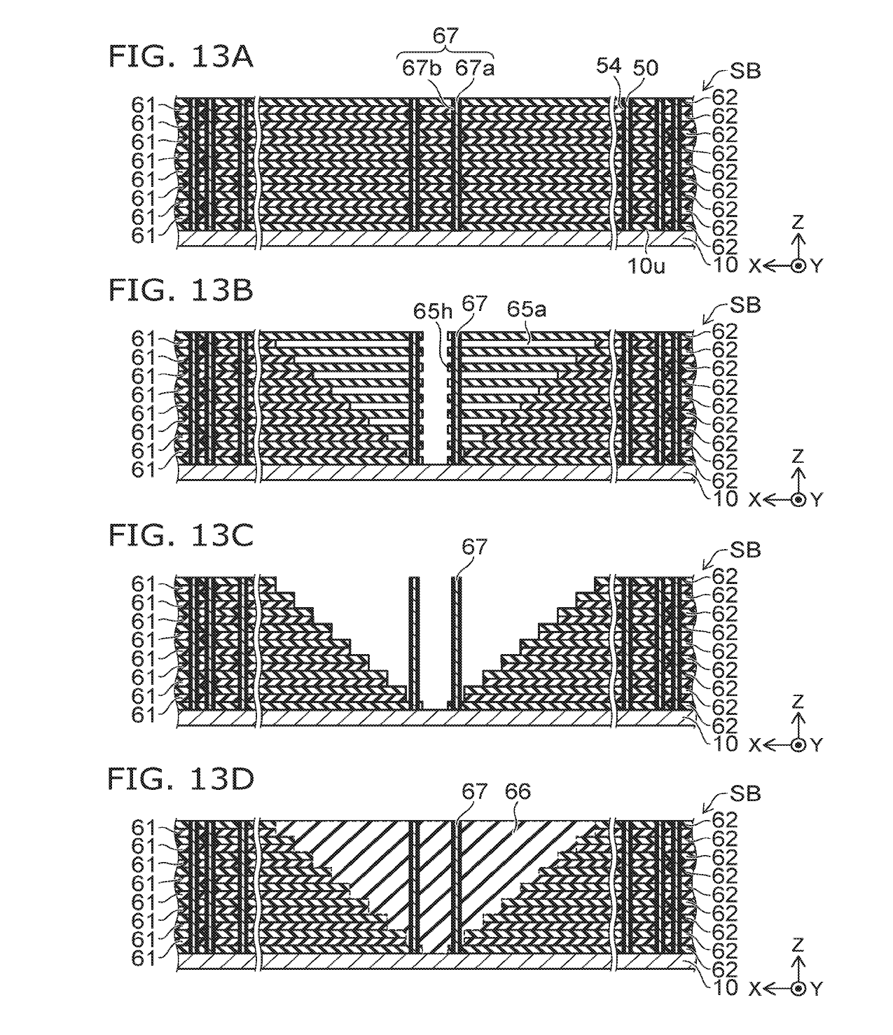

FIG. 13A through FIG. 13D are schematic cross-sectional views illustrating another method of manufacturing the semiconductor memory device according to the first embodiment.

As shown in FIG. 13A, the semiconductor pillars 50 and the memory films 54 extending in the first direction are formed in the structure SB. Further, the pillar sections 67 each piercing the structure SB in the first direction is formed. The pillar sections 67 each includes the core section 67a extending in the first direction, and the intermediate section 67b provided between the core section 67a and the structure SB.

As shown in FIG. 13B, a part of each of the plurality of first films 61 is removed. A part having a stepped shape is formed in the end portions of the plurality of first films 61. In this process, the process described with respect to the first through third manufacturing methods, for example, is performed. The midair parts of the plurality of second films 62 are held by the pillar sections 67.

As shown in FIG. 13C, the midair part of each of the plurality of second films 62 is removed. The anisotropic etching using RIE described with reference to FIG. 7B, for example, is performed. On this occasion, a part of the intermediate section 67b included in the pillar section 67 can also be removed. In the case in which, for example, the intermediate section 67b includes the stacked film of the film including silicon nitride and the film including silicon oxide, a part of each of these films can also be removed.

As shown in FIG. 13D, the space thus formed is filled with the insulating material 66.

As described above, the manufacturing method further includes a process (FIG. 13C) of removing at least a part of the portion (the midair part), which is not sandwiched by the plurality of first films 61 in the first direction, of each of the plurality of second films 62 between the process (FIG. 13B) of removing a part of each of the plurality of first films 61 and the process (FIG. 13D) of filling the space with the insulating material 66.

The process of filling the space with the insulating material 66 includes further filling the space formed by the removing at least a part of the midair part (the part not sandwiched by the first films 61) of the second films 62 with the insulating material 66 in addition to the first space 65a (the area from which a part of each of the plurality of first films 61 is removed).

In this manufacturing method, the plurality of second films 62 are held by the pillar sections 67 in the process of removing a part of each of plurality of the first films 61. Thus, the second films 62 are inhibited from being broken. Further, the midair part of each of the plurality of second films 62 is removed after removing a part of each of the plurality of first films 61. Thus, the influence of the breakage of the second films 62 is further suppressed.

### Second Embodiment

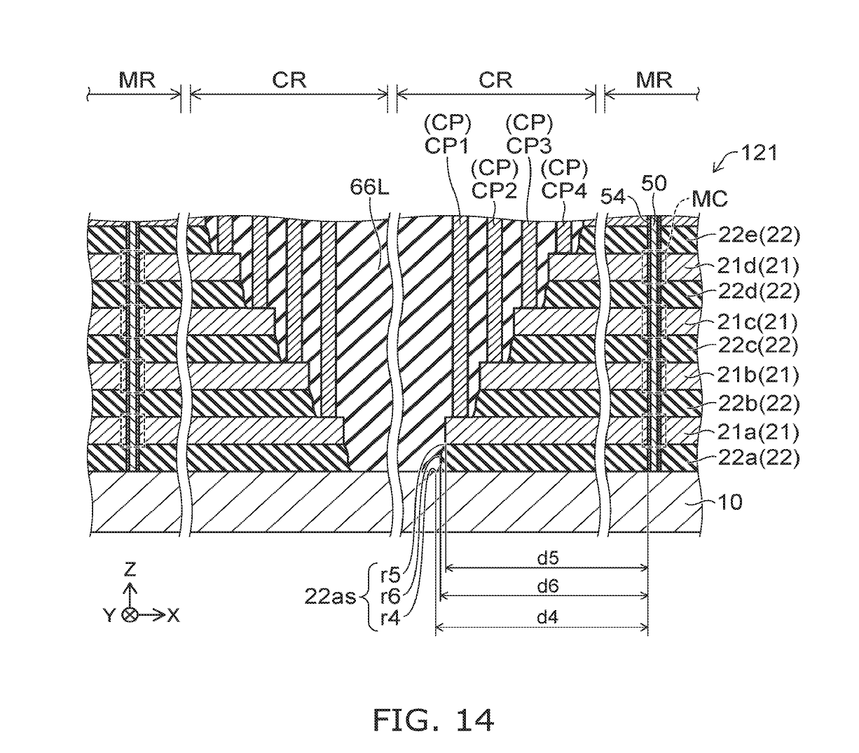

FIG. 14 is a schematic cross-sectional view illustrating a semiconductor memory device according to a second embodiment.

As shown in FIG. 14, a semiconductor memory device 121 according to the embodiment also includes the stacked body ML, the semiconductor pillars 50, and the memory films 54. The stacked body ML includes the plurality of conductive layers 21 (e.g., the first through fourth conductive layers 21a through 21d) and the plurality of insulating layers 22 (e.g., the first through fourth insulating layers 22a through 22d). In this example, a central portion in the thickness direction of one end portion of each of the insulating layers 22 is receding. The rest of the configuration is substantially the same as, for example, the configuration of the semiconductor memory device 111.

An example of the recession of the central portion of the end portion of each of the insulating layers 22 will be described. The stacked body ML includes the first conductive layer 21a, the second conductive layer 21b, and the first insulating layer 22a.

The second conductive layer 21b is separated from the first conductive layer 21a in the first direction (the Z-axis direction). The first insulating layer 22a is provided between the first conductive layer 21a and the second conductive layer 21b. The semiconductor pillars 50 each extends in the first direction through the stacked body ML. The memory film 54 is provided between the semiconductor pillar 50 and the stacked body ML. The memory cells MC are formed between the plurality of conductive layers 21 and the semiconductor pillar 50.

The first insulating layer 22a includes an end surface 22as. The end surface 22as is separated from the memory film 54 in the second direction (the X-axis direction in this example) crossing the first direction. The end surface 22as crosses the second direction.

The end surface 22as includes fourth through sixth regions r4 through r6. The position in the first direction of the fourth region r4 is located between the position in the first direction of the sixth region r6 and the position in the first direction of the first conductive layer 21a. The position in the first direction of the fifth region r5 is located between the position in the first direction of the sixth region r6 and the position in the first direction of the second conductive layer 21b.

As shown in FIG. 14, a sixth distance d6 along the second direction between the sixth region r6 and the memory film 54 is shorter than a fourth distance d4 along the second direction between the fourth region r4 and the memory film 54.

In the example, the sixth distance d6 is longer than a fifth distance d5 along the second direction between the fifth region r5 and the memory film 54. In this configuration, between the second conductive layer 21b and the lower body 10, there is disposed the first conductive layer 21a. Therefore, the distance between the end surface 22as and the memory film 54 is long on the lower body 10 side of the first insulating layer 22a, and the distance decreases as the distance from the lower body 10 increases.

In other words, the distance between the end surface 22as and the memory film 54 decreases along a direction from the bottom toward the top. In other words, the fourth distance d4 is shorter than the sixth distance d6, and the fifth distance d5 is shorter than the sixth distance d6. In other words, the end surface 22as is tilted. The end surface 22as has a positive tapered shape.

In the semiconductor memory device 121, since the end surface 22as of the first insulating layer 22a has the positive tapered shape, breakage in the end portion of the first insulating layer 22a is suppressed. Thus, high positional accuracy can be obtained. Foreign matters are inhibited from being generated, and the yield ratio is improved.

Also in this example, in the connection regions CR, the positions of end portions of the plurality of conductive layers 21 vary to form a stepped shape. In other words, the distances between the end portions of the plurality of conductive layers 21 and the memory film 54 decrease as the distance from the lower body 10 increases. By causing the shape of the plurality of conductive layers 21 to have the stepped shape, connection with the connection sections CP becomes easy. On the part having the stepped shape, there is provided the insulating section 66L.

In the case in which the insulating layers 22 include silicon oxide, and the insulating section 66L includes silicon oxide, the boundary between the insulating layers 22 and the insulating section 66L is unclear in some cases.

In the semiconductor memory device 121, the adhesion of the first insulating layer 22a can be enhanced in, for example, a part including the end surface 22as of the first insulating layer 22a. For example, the connection regions CR can be made smaller. The memory capacity can be increased.

The semiconductor memory device 121 can be manufactured using, for example, an eighth manufacturing method described below.

(Eighth Manufacturing Method)

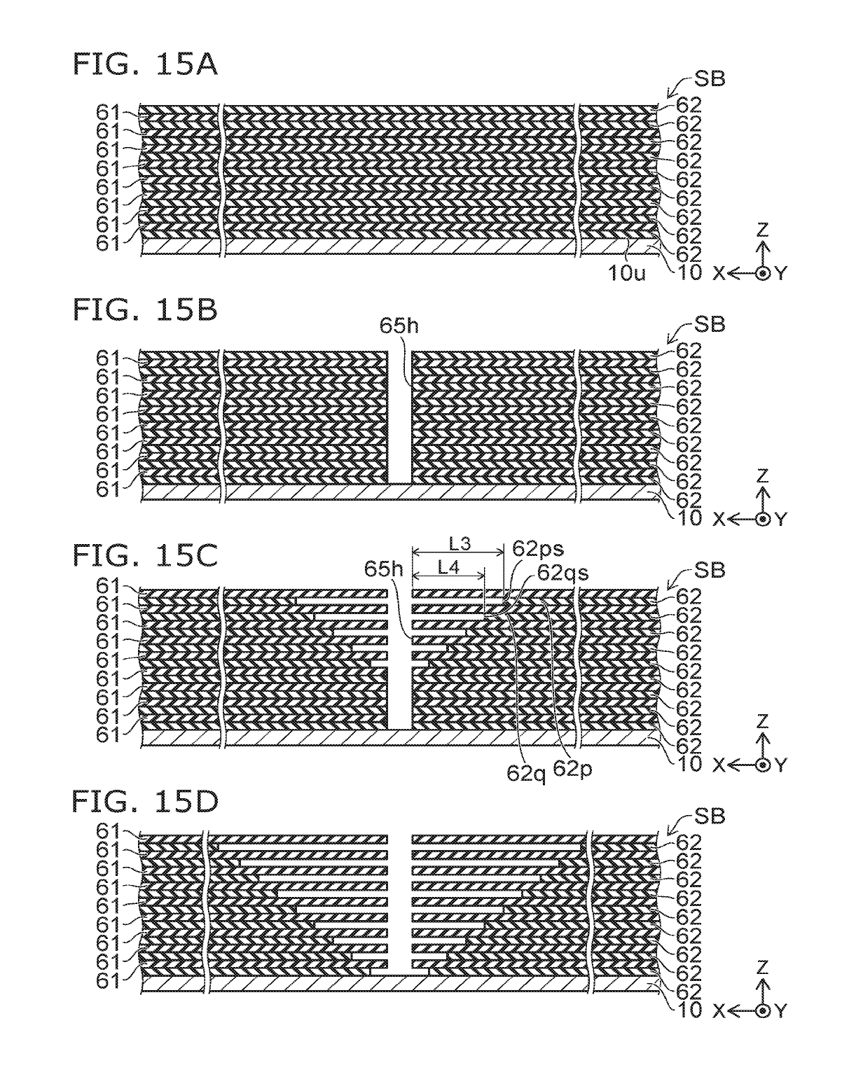

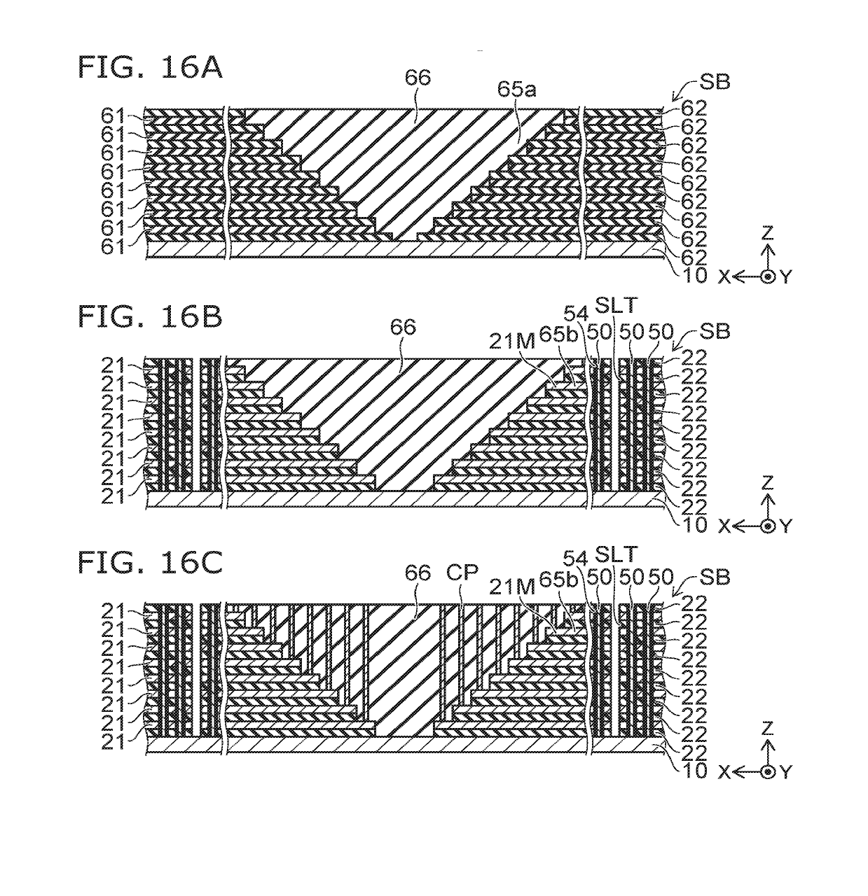

FIG. 15A through FIG. 15D and FIG. 16A through FIG. 16C are schematic cross-sectional views illustrating a method of manufacturing the semiconductor memory device according to the second embodiment.

As shown in FIG. 15A, the structure SB is formed on the lower body 10. The structure SB is provided on the surface 10u of the lower body 10. The structure SB includes the plurality of first films 61 and the plurality of second films 62 alternately stacked in the first direction. The first direction crosses the surface 10u of the lower body 10. The first direction is substantially perpendicular to the surface 10u. The first films 61 each includes, for example, silicon nitride. The second films 62 each includes, for example, silicon oxide.

As shown in FIG. 15B, the trench 65h is formed in the structure SB. On the inner side of the trench 65h of the structure SB, the plurality of first films 61 and the plurality of second films 62 are exposed.

As shown in FIG. 15C, a part of each of the plurality of second films 62 exposed on the inner side of the trench 65h is removed. This process can be performed by, for example, wet etching. In the case in which the second films 62 each includes silicon oxide, a hydrofluoric acid solution, for example, is used as an etchant of this process.

In this manufacturing method, the rate of the removing the second films 62 varies along the first direction.

For example, one (the second film 62p) of the plurality of second films 62 includes a third side surface 62ps. The third side surface 62ps crosses the second direction (the X-axis direction) perpendicular to the first direction. Another (the second film 62q) of the plurality of second films is located between the one (the second film 62p) of the plurality of second films 62 and the lower body 10. The second film 62q has a fourth side surface 62qs. The fourth side surface 62qs crosses the second direction (the X-axis direction). A fourth distance L4 along the second direction between the trench 65h and the fourth side surface 62qs is shorter than a third distance L3 along the second direction between the trench 65h and the third side surface 62ps.

In the process of removing a part of each of the plurality of second films 62, the etching rate of the second films 62 at the position far from, the lower body 10 is higher (faster) than the etching rate of the second films 62 at the position near to the lower body 10. Such a variation in the etching rate can be obtained from the fact that, for example, the etching rate of the etchant supplied to the trench 65h is high at the position far from the lower body 10, and is low at the position near to the lower body 10. For example, the concentration of the component causing a contribution to etching in the etchant is higher at the position far from the lower body 10 (i.e., the position near to the opening section of the trench 65h) than at the position near to the lower body 10. Thus, such a difference in etching rate as described above can be formed.

Thus, as shown in FIG. 15D, the stepped shape can be formed in the end portions of the plurality of second films 62.

As shown in FIG. 16A, a part of each of the plurality of first films 61 is removed after the process of removing a part of each of the plurality of second films 62. For example, an RIE process is performed. For example, an anisotropic etching is performed using RIE. After the process of removing a part of each of the plurality of second films 62, the second film 62 is not provided on the part of each of the plurality of first films 61. In other words, after the process of removing a part of each of the plurality of second films 62, the part of each of the plurality of first films 61 is not covered with the second film 62. By the removing the part of each of the plurality of first films 61, each of the end portions of the plurality of first films 61 becomes to follow the end portion of the second film 62 adjacent to the upper side of the first film 61. Thus, the stepped shape is provided to the plurality of first films 61.

Subsequently, a part of each of the second films 62 is removed to expose the part of each of the first films 61 having been covered with the second film 62.

As shown in FIG. 16B, a space (the first space 65a) formed by the removing the part of each of the plurality of first films 61 and the removing the part of each of the plurality of second films 62 is filled with the insulating material 66. The insulating material 66 forms an insulating section 66L.

After the process of filling the space with the insulating material 66 described above, the holes SLT are formed in the structure SB, and then the plurality of first films 61 are removed via the holes SLT.

A space (a second space 65b) formed by the removing the first films 61 is filled with a conductive material 21M. Thus, the plurality of conductive layers 21 arranged in the first direction are formed. The second films 62 respectively form the insulating layers 22.

In this example, in the process shown in FIG. 16C, the semiconductor pillars 50 and the memory films 54 are formed in the structure SB.

Subsequently, as shown in FIG. 16C, a part of the insulating material 66 is removed to form the contact holes. The contact holes reach each of the plurality of conductive layers 21, and each extends in the first direction. The contact holes are filled with a conductive material. Thus, the connection sections CP are formed.

In the eighth manufacturing method described above, when the plurality of second films 62 are etched via the trench 65h, there is used the fact that the etching rate differs along the height direction (the first direction). The difference in the etching rate is caused by a difference in concentration of the component causing a contribution to etching in the etchant between, for example, an area near to the opening section of the trench 65h and a deep area of the trench 65h.

For example, the etchant is used in the process of removing a part of each of the plurality of second films 62. The etching rate of the one (the second film 62p) of the plurality of second films 62 with respect to the etchant is higher (faster) than the etching rate of the other one (the second film 62q) of the plurality of second films 62.

The plurality of second films 62 are processed to have the stepped shape using such a difference in etching rate.

Thus, for example, the process becomes simple. For example, a variation in processing is suppressed. For example, the accuracy of the positions of the end portions of the plurality of second films 62 can be improved. Thus, the accuracy of the positions of the end portions of the plurality of first films 61 can be improved. Thus, the connection regions CR can be narrowed. Thus, the semiconductor memory device with a high memory capacity can be manufactured.

(Ninth Manufacturing Method)

The semiconductor memory device 121 described above can also be manufactured using a ninth manufacturing method described below.

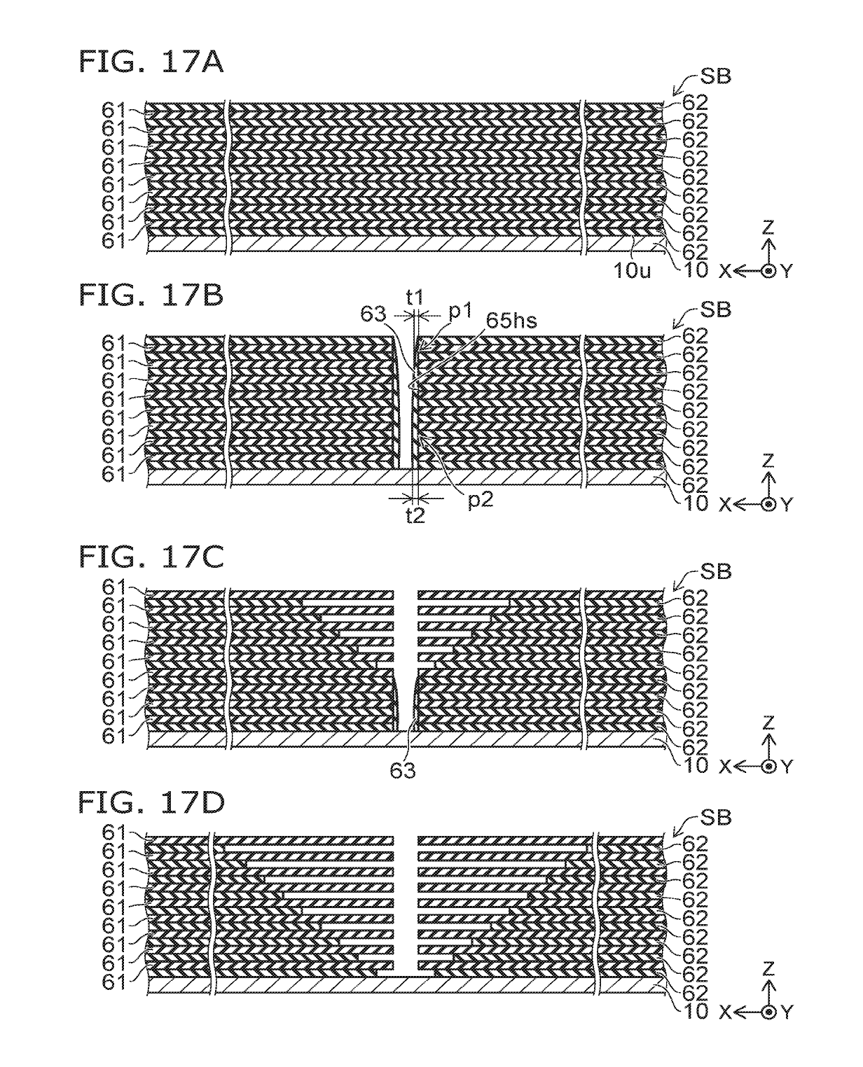

FIG. 17A through FIG. 17D are schematic cross-sectional views illustrating another method of manufacturing the semiconductor memory device according to the second embodiment.

As shown in FIG. 17A, also in this example, there is provided the structure SB on the lower body 10.

As shown in FIG. 17B, the third film 63 is formed on the sidewall 65hs of the trench 65h between the process (e.g., FIG. 15B) of forming the trench 65h and the process (see, e.g., FIG. 15C) of removing a part of each of the second films 62. The third film 63 includes, for example, the material included in the second films 62. The second films 62 include, for example, silicon oxide, and the third film 63 includes silicon oxide.

Further, the third film 63 is processed between the process of forming the third film 63 and the process (FIG. 15C) of removing a part of each of the plurality of second films 62. In the processing, the length t1 along the second direction (the X-axis direction) of the third film 63 at the first position p1 distant from the lower body 10 is made shorter than the length t2 along the second direction of the third film 63 at the second position p2 located between the first position p1 and the lower body 10.

In the processing of the third film 63, there is used the fact that, for example, the etching rate of the third film 63 is high in the part near to the opening section of the trench 65h.

As shown in FIG. 17C, a part of each of the plurality of second films 62 is gradually removed while gradually removing the third film 63.

Specifically, the process of removing a part of each of the plurality of second films 62 includes a process of removing the part corresponding to the first position p1 of the third film 63, and then removing at least a part of one of the plurality of second films 62, which has been exposed by the removing the part corresponding to the first position p1. Further, the process of removing a part of each of the plurality of second films 62 includes a process of removing the part corresponding to the second position p2 of the third film 63 after the removing the part corresponding to the first position p1 described above, and then removing at least a part of another of the second films 62, which has been exposed by the removing the part corresponding to the second position p2.

Subsequently, the processes described with reference to FIG. 16A through FIG. 16C, for example, are performed. Thus, the semiconductor memory device 121 can be formed.

As described above, by the processing of the third film 63, the time of start of the removing a part of each of the plurality of second films 62 is controlled. In other words, after starting the removing the second films 62 at the position distant from the lower body 10, the removing the second films 62 at the position near to the lower body 10 is started.

Thus, the accuracy of the positions of the end portions of the plurality of second films 62 can be improved. The accuracy of the positions of the end portions of the plurality of first films 61 can be improved. Thus, the connection regions CR can be narrowed. Thus, the semiconductor memory device with a high memory capacity can be manufactured.

(Tenth Manufacturing Method)

The semiconductor memory device 121 can also be manufactured using a tenth manufacturing method described below.

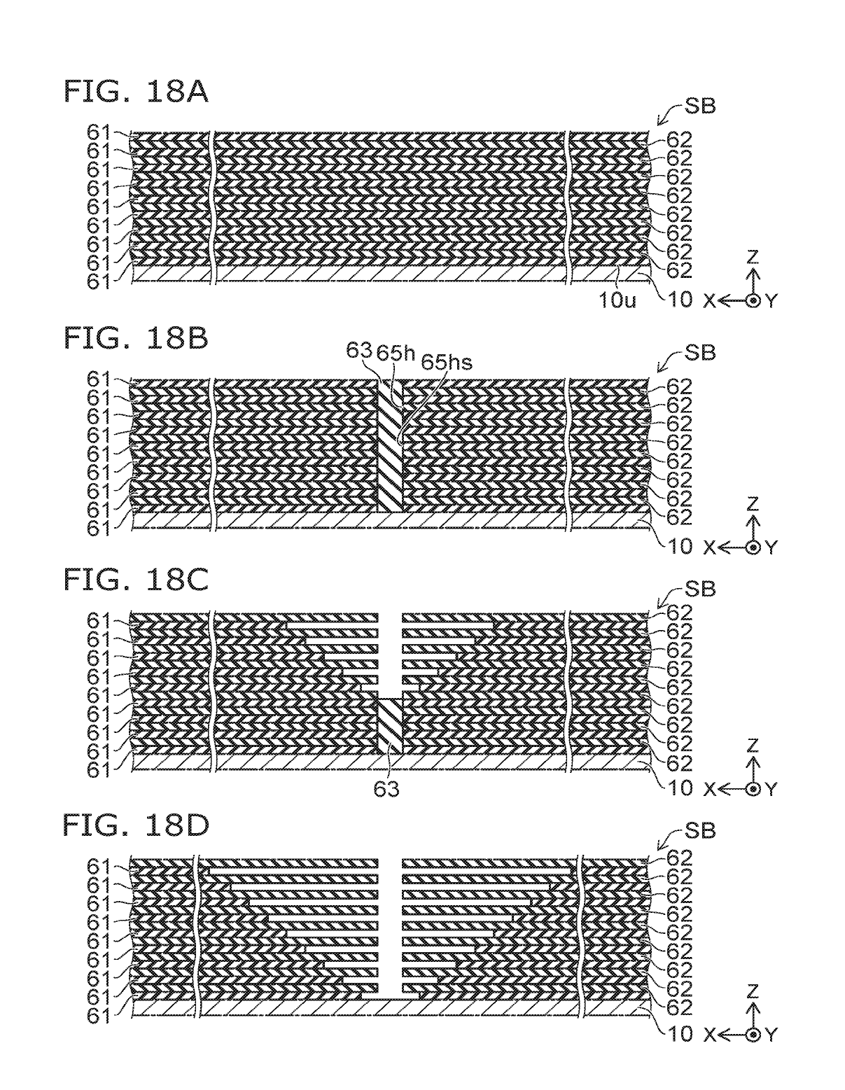

FIG. 18A through FIG. 18D are schematic cross-sectional views illustrating another method of manufacturing the semiconductor memory device according to the second embodiment.

As shown in FIG. 18A, also in this example, there is provided the structure SB on the lower body 10.

As shown in FIG. 18B, the third film 63 is formed in the trench 15h between the process (FIG. 15B) of forming the trench 65h and the process (FIG. 15C) of removing a part of each of the plurality of second films 62.

As shown in FIG. 18C, a part of each of the plurality of second films 62 is removed while removing the third film 63. Specifically, the process of removing a part of each of the plurality of second films 62 includes a process of removing a part of the third film 63 to cause the third film 63 to recede along the first direction, and then removing at least a part of one of the plurality of second films 62, which has been exposed by the recession of the third film 63. Further, the process of removing a part of each of the plurality of second films 62 further includes a process of causing the third film 63 to further recede after the recession of the third film 63 described above, and then removing at least a part of another of the plurality of second films 62, which has been exposed by the further recession of the third film 63.

Subsequently, the processes described with reference to FIG. 16A through FIG. 16C, for example, are performed. Thus, the semiconductor memory device 121 can be formed.

Also in this case, by the processing of the third film 63, the time of start of the removing a part of each of the plurality of second films 62 is controlled. In other words, after starting the removing the second films 62 at the position distant from the lower body 10, the removing the second films 62 at the position near to the lower body 10 is started.

Thus, the accuracy of the positions of the end portions of the plurality of second films 62 can be improved. The accuracy of the positions of the end portions of the plurality of first films 61 can be improved. Thus, the connection regions CR can be narrowed. Thus, the semiconductor memory device with a high memory capacity can be manufactured.

In the eighth through tenth manufacturing methods described above, it is also possible to form the pillar sections 67 piercing the structure SB in the first direction prior to the process of forming the trench 65h as described with reference to FIG. 10A through FIG. 10C, and FIG. 11A through FIG. 11C. In this case, the trench 65h is separated from the pillar sections 67.

Furthermore, it is also possible for the eighth though tenth manufacturing method described above to further include a process of forming the memory cells MC. Specifically, a process of forming the memory holes piercing the structure SB in the first direction is performed prior to the process (e.g., FIG. 15C) of removing the plurality of plurality of second films 62. Further, the memory film 54 is formed on the inner wall surface of each of the memory holes. Further, after forming the memory films 54, it is also possible to form the semiconductor pillar 50 extending in the first direction in the remaining space of each of the memory holes.

(Another Semiconductor Memory Device According to Second Embodiment)

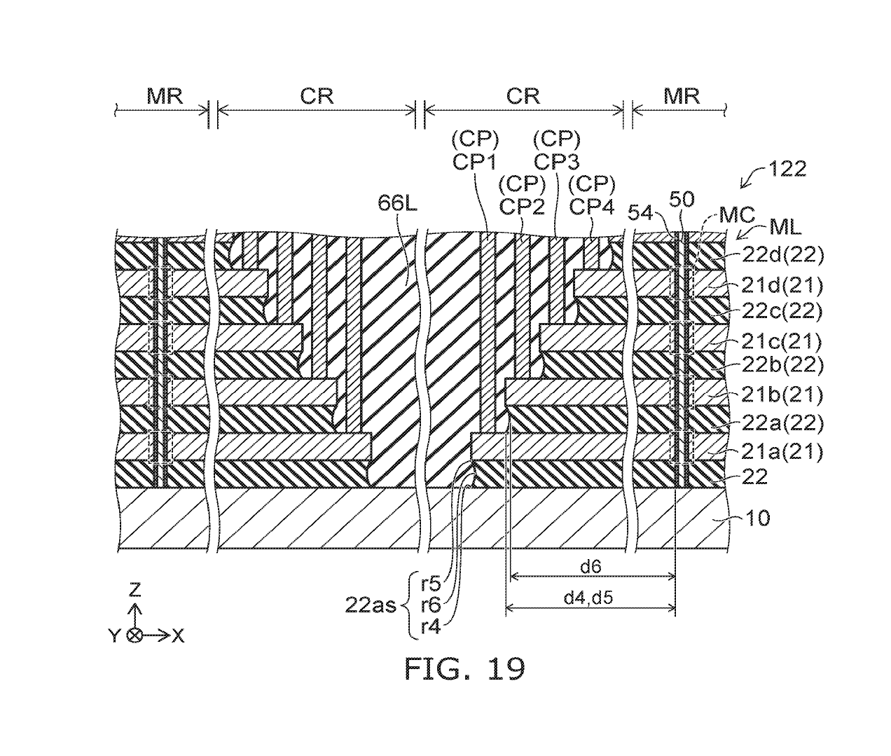

FIG. 19 is a schematic cross-sectional view illustrating another semiconductor memory device according to the second embodiment.

As shown in FIG. 19, a semiconductor memory device 122 according to the embodiment also includes the stacked body ML, the semiconductor pillars 50, and the memory films 54. In the semiconductor memory device 122, the sixth distance d6 along the second direction (the X-axis direction) between the sixth region r6 and the memory film 54 is shorter than the fourth distance d4 along the second direction between the fourth region r4 and the memory film 54 in the end surface 22as of the first insulating layer 22a. Further, the sixth distance d6 is shorter than a fifth distance d5 along the second direction between the fifth region r5 and the memory film 54. The rest of the configuration is substantially the same as, for example, the configuration of the semiconductor memory device 121.

As described above, in the embodiment, the end surface 22as of the first insulating layer 22a can be receding in the central portion.

(Eleventh Manufacturing Method)

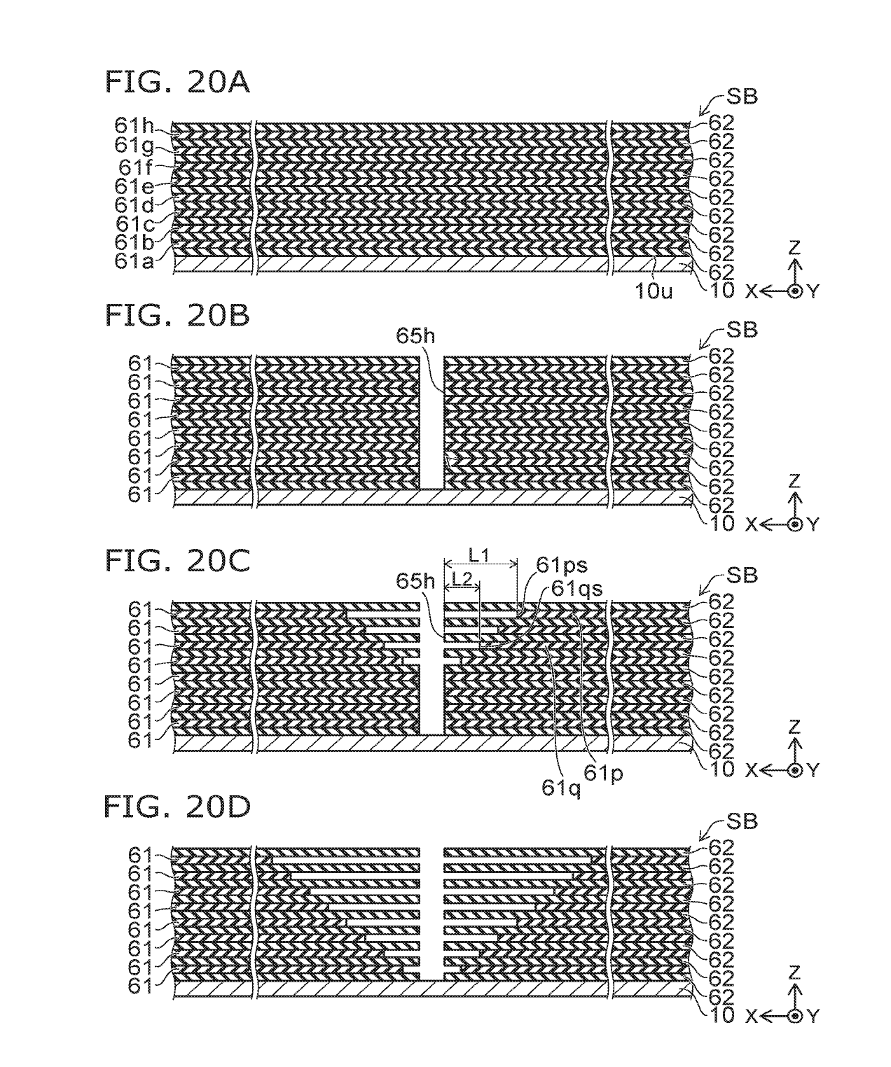

FIG. 20A through FIG. 20D are schematic cross-sectional views illustrating another method of manufacturing the semiconductor memory device according to the embodiment.

As shown in FIG. 20A, the structure SB is formed on the lower body 10. The structure SB includes the plurality of first films 61 and the plurality of second films 62 alternately stacked along the Z-axis direction (the first direction). The first direction (the Z-axis direction) crosses the surface 10u of the lower body 10.

In this example, the characteristics of the plurality of first films 61 differ along the stacking direction (the first direction). For example, the plurality of first films 61 include film 61a through film 61h.

As described later, a part of each of the plurality of first films 61 is removed. In the removal, etching using an etchant is performed. The etching rate of the film 61a near to the lower body 10 is lower than the etching rate of the film 61h far from the lower body 10.

For example, in the formation of the first films 61, by varying the shape condition, the etching rate can be controlled. In the formation of the first films 61, by varying the shape condition, the density of the first film 61 can be controlled. In the formation of the first films 61, by varying the shape condition, an amount (the concentration) of a specific chemical bond included in the first film 61 can be controlled. For example, by varying the density, the etching rate varies. For example, by varying the amount of the specific chemical bond, the etching rate varies.

As described above, in this example, the etching rate of one (e.g., the film 61h on the upper side) of the plurality of first films 61 with respect to an etchant used in the process of removing a part of each of the plurality of first films 61 is higher than the etching rate of another (e.g., the film 61a on the lower side) of the plurality of first films 61 with respect to this etchant. The film 61h on the upper side corresponds to, for example, the first film 61p (see FIG. 20C). The film 61a on the lower side corresponds to, for example, the first film 61q (see FIG. 20C).

In other words, the characteristics of the film are changed between the first film 61p and the first film 61q so that a difference occurs in the removing a part of each of the plurality of first films 61. For example, the density of one (the first film 61p) of the plurality of first films 61 is lower than the density of another (the first film 61q) of the plurality of first films 61.

Thus, the etching rate of the first film 61 on the upper side becomes higher than the etching rate of the first film 61 on the lower side.

After forming such a structure SB, the trench 65h is formed as shown in FIG. 20B.

As shown in FIG. 20C, a part of each of the plurality of first films 61 exposed inside the trench 65h is removed. In the removing a part of each of the plurality of first films 61, an amount of removing the first film 61 becomes large on the upper side compared to the lower side.

Thus, as shown in FIG. 20D, the stepped shape is formed in the plurality of first films 61.

Subsequently, the processes described with reference to FIG. 3A through FIG. 3C are performed, and thus the semiconductor memory device 111, for example, is formed.

In the eleventh manufacturing method, it is also possible to remove a part of each of the second films 62 in accordance with the stepped shape of the first films 61. Further, it is also possible to process the first films 61 using the third film 63. Further, it is also possible to provide the pillar sections 67. Further, it is also possible to form the memory holes piercing the structure SB in the first direction, form the memory film 54 on the inner wall surface of each of the memory holes, and form the semiconductor pillar 50 extending in the first direction in the remaining space of each of the memory holes.

In the case in which the plurality of first films 61 each includes silicon nitride, the etching rate of the silicon nitride with respect to the wet etching varies in accordance with the density (concentration) of a specific chemical bond included in silicon nitride. For example, a silicon nitride film includes an N—H bond and an Si—N bond. For example, at peaks of an infrared spectroscopic analysis, the peaks corresponding respectively to these bonds are detected. The wave number corresponding to the N—H bond is, for example, 900 cm⁻¹. The wave number corresponding to the Si—N bond is 3200 cm⁻¹. The ratio of the intensity of the peak of the N—H bond to the intensity of the peak of the Si—N bond is defined as an NH/SiN ratio.

For example, a phosphoric acid solution is used as the etchant. The phosphoric acid concentration is, for example, 90%. In this case, the etching rate with the NH/SiN ratio of 2% is assumed as 1. In this case, the etching rate with the NH/SiN ratio of 3.5% is about 2. The etching rate with the NH/SiN ratio of 7% becomes about 3.

In such a manner, the etching rate varies in accordance with the NH/SiN ratio. This characteristic can be used.

For example, in the infrared spectroscopic analysis, one (the first film 61p) of the plurality of first films 61 has a first peak corresponding to the bond (N—H bond) between hydrogen and nitrogen, and a second peak corresponding to the bond (Si—N bond) between silicon and nitrogen. In the infrared spectroscopic analysis, another (the first film 61q) of the plurality of first films 61 has a third peak corresponding to the bond between hydrogen and nitrogen, and a fourth peak corresponding to the bond between silicon and nitrogen.

The ratio (NH/SiN ratio) of the intensity of the third peak to the intensity of the fourth peak in the first film 61q on the lower side is lower than the ratio (NH/SiN ratio) of the intensity of the first peak to the intensity of the second peak in the first film 61p on the upper side. Thus, the etching rate in the first film 61q on the lower side becomes lower than the etching rate of the first film 61p on the upper side.

(Twelfth Manufacturing Method)

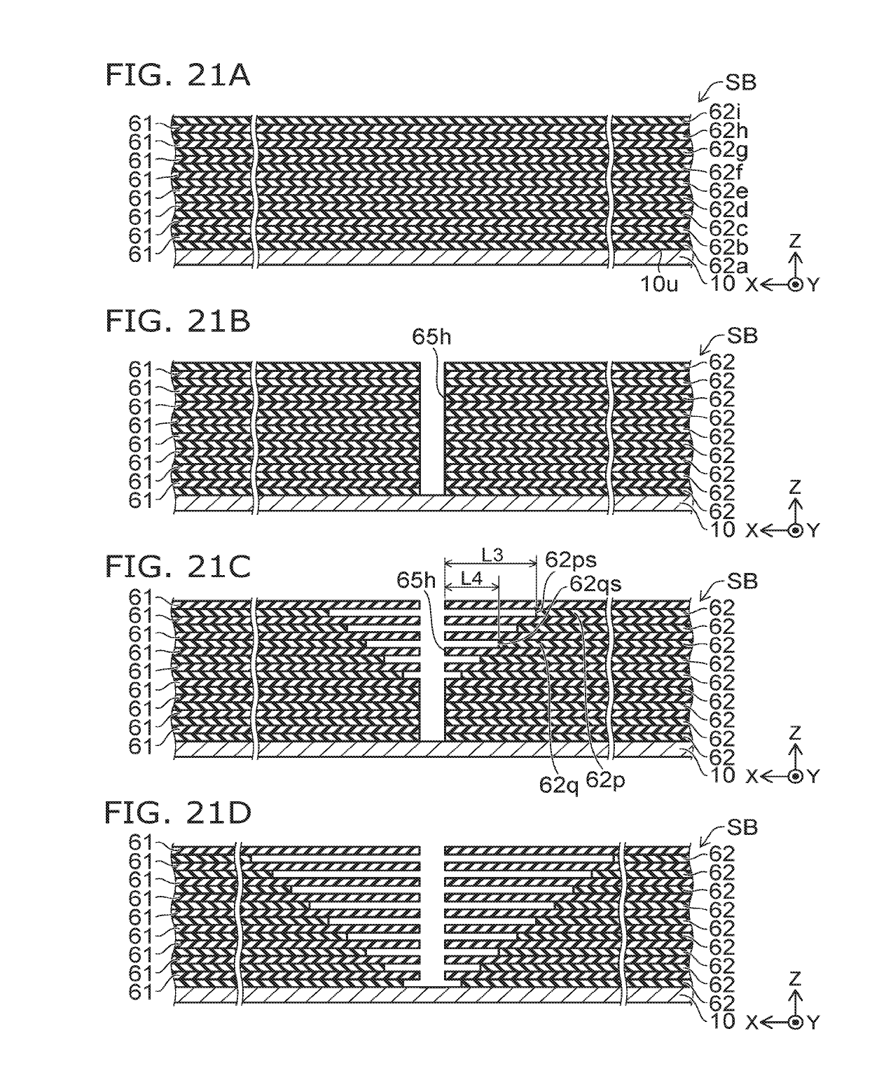

FIG. 21A through FIG. 21D are schematic cross-sectional views illustrating another method of manufacturing the semiconductor memory device according to the embodiment.

As shown in FIG. 21A, the structure SB is formed on the lower body 10. The structure SB includes the plurality of first films 61 and the plurality of second films 62 alternately stacked along the Z-axis direction (the first direction).

In this example, the characteristics of the plurality of second films 62 differ along the stacking direction (the first direction). For example, the plurality of second films 62 includes film 62a through film 62i.

As described later, a part of each of the plurality of second films 62 is removed. In the removal, etching using an etchant is performed. The etching rate of the film 62a near to the lower body 10 is lower than the etching rate of the film 62i far from the lower body 10.

For example, the density of one (the second film 62p, see FIG. 21C) of the plurality of second films 62 is lower than the density of another (the second film 62q, see FIG. 21C) of the plurality of second films 62.

After forming such a structure SB, the trench 65h is formed as shown in FIG. 21B.

As shown in FIG. 21C, a part of each of the plurality of second films 62 exposed inside the trench 65h is removed. In the removing a part of each of the plurality of second films 62, an amount of removing the second film 62 becomes large on the upper side compared to the lower side.

Thus, as shown in FIG. 21D, the stepped shape is formed in the plurality of second films 62.

Subsequently, the processes described with reference to FIG. 16A through FIG. 16C are performed, and thus the semiconductor memory device 121, for example, is formed.

In this twelfth manufacturing method, it is also possible to remove a part of each of the first films 61 in accordance with the stepped shape of the plurality of second films 62. Further, it is also possible to process the second films 62 using the third film 63. Further, it is also possible to provide the pillar sections 67. Further, it is also possible to form the memory holes piercing the structure SB in the first direction, form the memory film 54 on the inner wall surface of each of the memory holes, and form the semiconductor pillar 50 extending in the first direction in the remaining space of each of the memory holes.

In the case in which the plurality of second films 62 each includes silicon oxide, the etching rate of the silicon oxide with respect to the wet etching varies in accordance with the concentration of carbon included in silicon oxide. For example, DHF is used as the etchant of etching of silicon oxide. The concentration of DHF is, for example, 0.5%. On this occasion, the etching rate with the carbon concentration in silicon oxide of 10×10²² atm/cm³ is assumed as 1. The etching rate with the carbon concentration in silicon oxide of 8.5×10²² atm/cm³ is about 2. The etching rate with the carbon concentration in silicon oxide of 7×10²² atm/cm³ is about 3.

In such a manner, the etching rate varies in accordance with the carbon concentration in silicon oxide. This characteristic can be used.

Specifically, in the twelfth manufacturing method, the plurality of second films 62 include silicon oxide. The carbon concentration of one (the second film 62p on the upper side) of the plurality of second films 62 is lower than the carbon concentration of another (the second film 62q on the lower side) of the plurality of second films 62. Thus, the etching rate in the second film 62q on the lower side becomes lower than the etching rate of the second film 62p on the upper side.

(Thirteenth Manufacturing Method)

In the manufacturing method, the configuration of the plurality of first films 61 different in characteristic from each other described with respect to the eleventh manufacturing method and slimming of the mask are combined with each other.

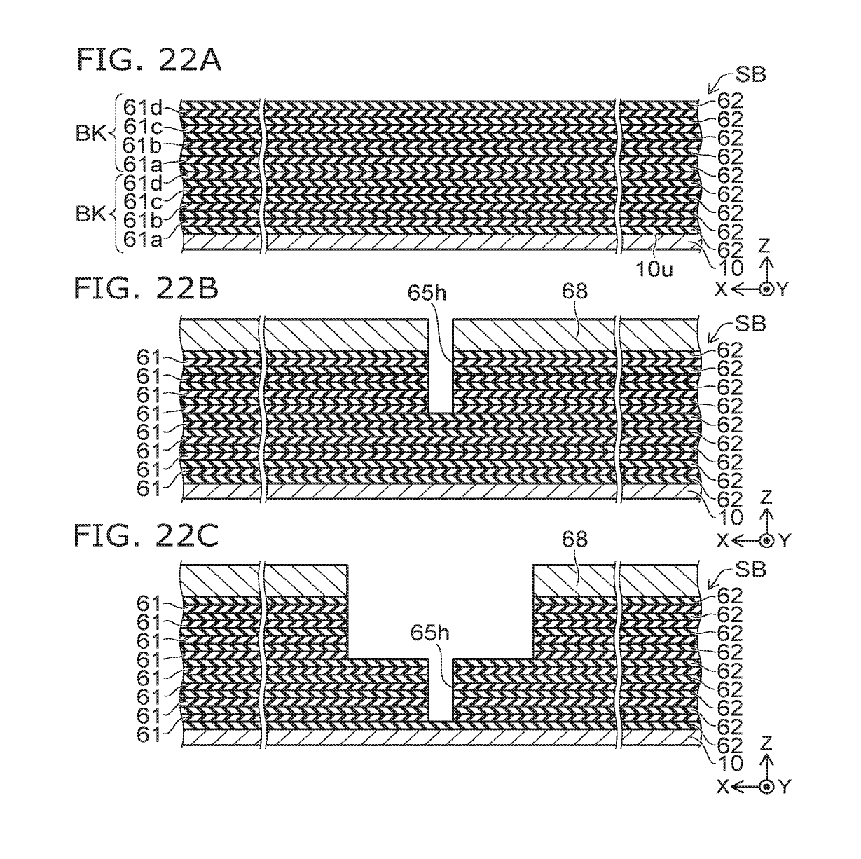

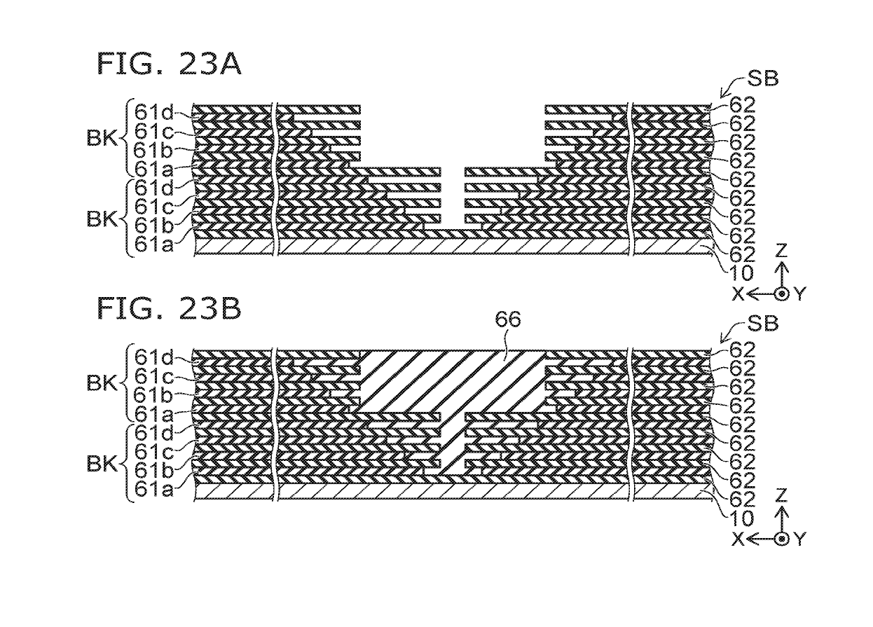

FIG. 22A through FIG. 22C, FIG. 23A, and FIG. 23B are schematic cross-sectional views illustrating another method of manufacturing the semiconductor memory device according to the embodiment.

As shown in FIG. 22A, the structure SB is formed on the lower body 10. The structure SB includes the plurality of first films 61 and the plurality of second films 62 alternately stacked along the Z-axis direction (the first direction).

In this example, the plurality of first films 61 are divided into a plurality of blocks BK. In one of the blocks BK, the characteristics of the plurality of first films 61 differ along the stacking direction (the first direction). For example, in one of the blocks BK, the plurality of first films 61 include film 61a through film 61d. Such blocks BK are stacked on one another.

In one of the blocks BK, the etching rate of the film 61a near to the lower body 10 is lower than the etching rate of the film 61d far from the lower body 10.

For example, in the formation of the first films 61, by varying the shape condition, the etching rate can be controlled. In the formation of the first films 61, by varying the shape condition, the density of the first film 61 can be controlled. In the formation of the first films 61, by varying the shape condition, an amount (the concentration) of a specific chemical bond included in the first film 61 can be controlled. For example, by varying the density, the etching rate varies. For example, by varying the concentration of a chemical bond, the etching rate varies.

As shown in FIG. 22B, a mask 68 is formed on the structure SB. Further, the mask 68 is processed, and then the trench 65h is formed in a part of the structure SB using the mask 68.

As shown in FIG. 22C, the mask 68 is slimmed. The structure SB is processed using the mask 68 thus slimmed. Thus, a step is provided to the trench 65h.

As shown in FIG. 23A, a part of each of the plurality of first films 61 exposed in the trench 65h is removed. On this occasion, in each of the plurality of blocks BK, the etching rate is made different between the plurality of first films 61 (the film 61a through the film 61d). Thus, in each of the plurality of blocks BK, the recession of the first film 61 is made different between the first films 61. Thus, the stepped shape can be provided to the plurality of first films 61.

As shown in FIG. 23B, the space thus formed is filled with the insulating material 66. Subsequently, the processes described with reference to FIG. 3A through FIG. 3C, for example, are performed. Thus, the semiconductor memory device is formed.

In the manufacturing method, it is also possible to remove a part of each of the second films 62 in accordance with the stepped shape of the first films 61. Further, it is also possible to process the first films 61 using the third film 63. Further, it is also possible to provide the pillar sections 67. Further, it is also possible to form the memory holes piercing the structure SB in the first direction, form the memory film 54 on the inner wall surface of each of the memory holes, and form the semiconductor pillar 50 extending in the first direction in the remaining space of each of the memory holes.

(Another Semiconductor Memory Device According to Embodiment)

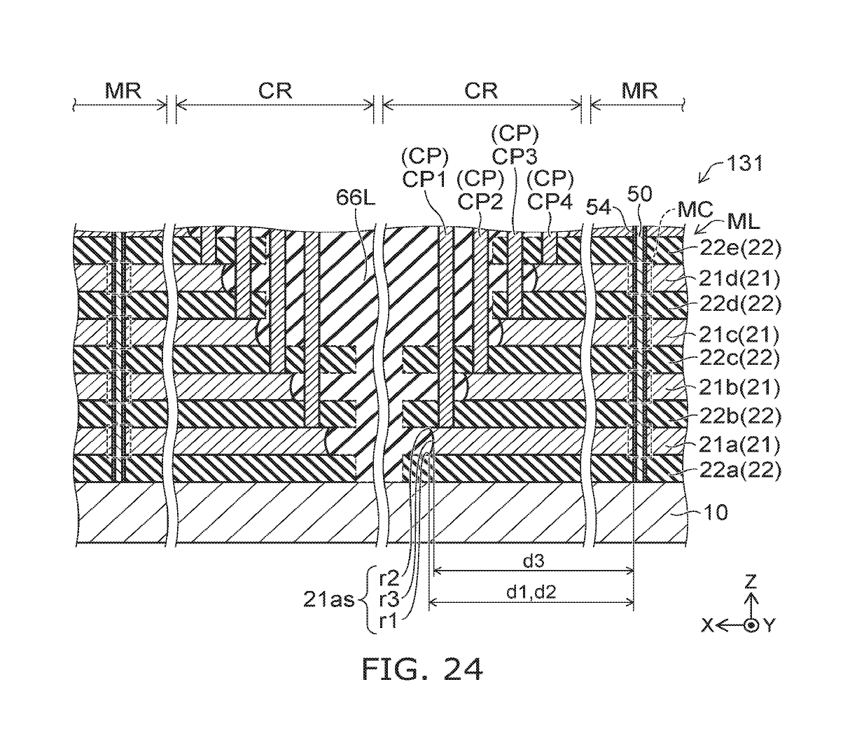

FIG. 24 is a schematic cross-sectional view illustrating another semiconductor memory device according to the embodiment.

As shown in FIG. 24, in another semiconductor memory device 131 according to the embodiment, the positions (the positions along the second direction) of some end portions of the plurality of insulating layers 22 are made different in the first direction from each other. In this example, the insulating layers 22 include first through fifth insulating layers 22a through 22e. The positions in the second direction (the X-axis direction) of the respective end portions (the end portions on the opposite side to the memory film 54) of the first through third insulating layers 22a through 22c are different from the positions in the second direction (the X-axis direction) of the end portions (the end portions on the opposite side to the memory film 54) of the fourth and fifth insulating layers 22d and 22e. The rest of the configuration is substantially the same as the configuration of the semiconductor memory device 111, and therefore, the description thereof will be omitted.

Such a semiconductor memory device 131 is formed using, for example, the thirteenth manufacturing method described above. Also in the semiconductor memory device 131, the memory capacity can be increased.

(Fourteenth Manufacturing Method)

In the manufacturing method, the configuration of the plurality of second films 62 different in characteristic from each other described with respect to the twelfth manufacturing method and slimming of the mask are combined with each other.

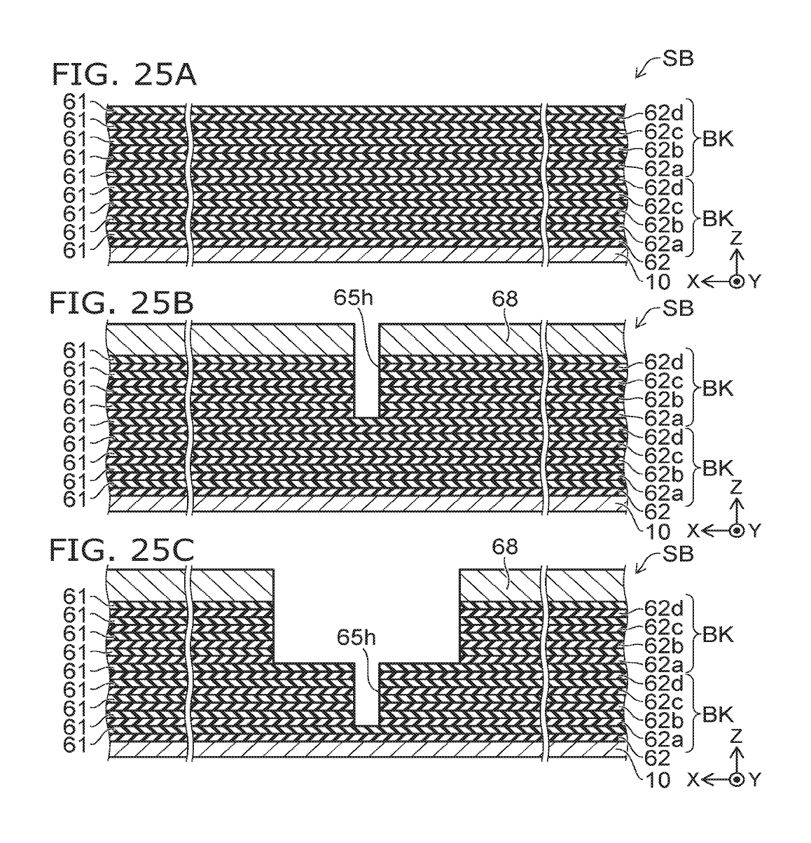

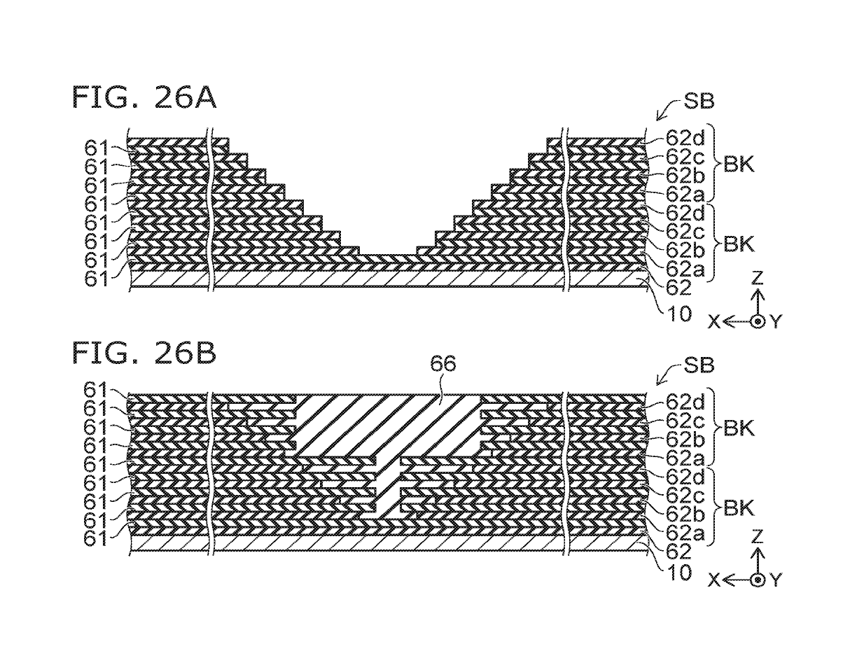

FIG. 25A through FIG. 25C, FIG. 26A, and FIG. 26B are schematic cross-sectional views illustrating another method of manufacturing the semiconductor memory device according to the embodiment.

As shown in FIG. 25A, the structure SB is formed on the lower body 10. The structure SB includes the plurality of first films 61 and the plurality of second films 62 alternately stacked along the Z-axis direction (the first direction).

In this example, the plurality of second films 62 are divided into a plurality of blocks BK. In one of the blocks BK, the characteristics of the plurality of second films 62 differ along the stacking direction (the first direction). For example, in one of the blocks BK, the plurality of second films 62 include film 62a through film 62d. Such blocks BK are stacked on one another.

In one of the blocks BK, the etching rate of the film 62a near to the lower body 10 is lower than the etching rate of the film 62d far from the lower body 10.

For example, in the formation of the second films 62, by varying the shape condition, the etching rate can be controlled. In the formation of the second films 62, by varying the shape condition, the density of the second film 62 can be controlled. In the formation of the second films 62, by varying the shape condition, the concentration of carbon included in the second film 62 can be controlled. For example, by varying the carbon concentration, the etching rate varies.

As shown in FIG. 25B, the mask 68 is formed on the structure SB. Further, the mask 68 is processed, and then the trench 65h is formed in a part of the structure SB using the mask 68.

As shown in FIG. 25C, the mask 68 is slimmed. The structure SB is processed using the mask 68 thus slimmed. Thus, a step is provided to the trench 65h.

As shown in FIG. 26A, a part of each of the plurality of second films 62 exposed in the trench 65h is removed. On this occasion, in each of the plurality of blocks BK, the etching rate is made different between the plurality of second films 62 (the film 62a through the film 62d). Thus, in each of the plurality of blocks BK, the recession of the second film 62 is made different between the second films 62. Thus, the stepped shape can be provided to the plurality of second films 62.

Subsequently, the plurality of first films 61 are processed in accordance with the stepped shape of the second films 62 as needed.

As shown in FIG. 26B, the space thus formed is filled with the insulating material 66. Subsequently, the processes described with reference to FIG. 16A and FIG. 16C, for example, are performed. Thus, the semiconductor memory device is formed.

In the manufacturing method, it is also possible to process the second films 62 using the third film 63. Further, it is also possible to provide the pillar sections 67. Further, it is also possible to form the memory holes piercing the structure SB in the first direction, form the memory film 54 on the inner wall surface of each of the memory holes, and form the semiconductor pillar 50 extending in the first direction in the remaining space of each of the memory holes.

Hereinafter, one specific example of the semiconductor device according to the embodiment will be described.

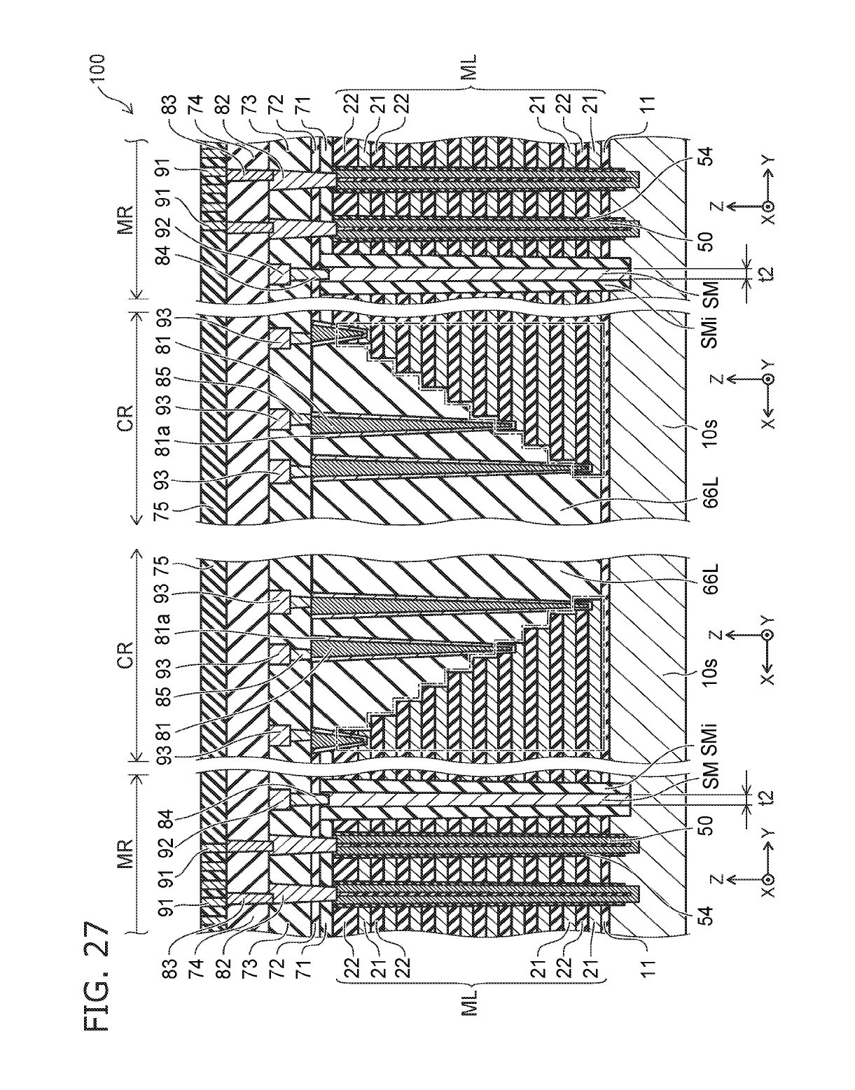

FIG. 27 is a schematic cross-sectional view illustrating a semiconductor memory device according to the embodiment.

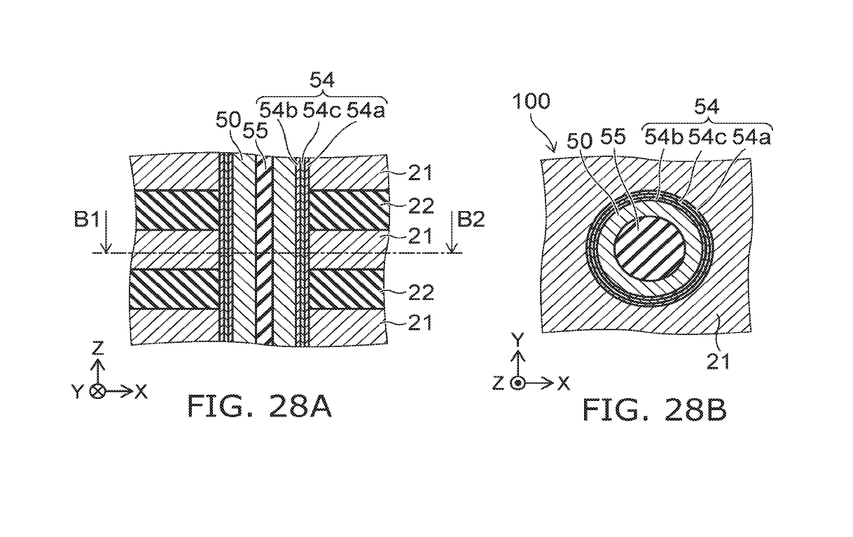

FIG. 28A and FIG. 28B are schematic cross-sectional views illustrating a part of the semiconductor memory device according to the embodiment.

FIG. 28B is a cross-sectional view along the line B1-B2 shown in FIG. 28A.

As shown in FIG. 27, in a semiconductor memory device 100 according to the embodiment, there is provided a substrate 10s (may be a conductive layer, for example). The substrate 10s is, for example, a silicon substrate. In this example, an insulating layer 11 is provided on the substrate 10s. On the insulating layer 11, there are provided the semiconductor pillars 50, the memory films 54, the stacked bodies ML, and source members SM. In this example, the insulating layer 11 corresponds to the lower body 10.

The semiconductor pillars 50 are electrically connected to the substrate 10s. The source member SM is disposed in the stacked body ML. The semiconductor pillar 50 and the source member SM are electrically connected to each other via the substrate 10s. The stacked body ML includes the plurality of conductive layers 21 and the plurality of insulating layers 22.

Between the stacked body ML and the semiconductor pillar 50, there is provided the memory film 54.

As shown in FIG. 28A and FIG. 28B, in this example, the semiconductor pillar 50 has a cylindrical shape. In the semiconductor pillar 50, there is provided a core section 55 extending in the first direction. The core section 55 has, for example, an insulation property.

The memory film 54 includes, for example, an outside film 54a, an inside film 54b, and an intermediate film 54c. The outside film 54a is provided between the semiconductor pillar 50 and the conductive layers 21. The inside film 54b is provided between the semiconductor pillar 50 and the outside film 54a. The intermediate film 54c is provided between the outside film 54a and the inside film 54b. The outside film 54a is, for example, a block insulating film. The intermediate film 54c is, for example, a charge storage film. The inside film 54b is, for example, a tunnel insulating film.

The outside film 54a and the inside film 54b each includes, for example, a silicon oxide. It is also possible for the outside film 54a and the inside film 54b to include Al₂O₃, Y₂O₃, La₂O₃, Gd₂O₃, Ce₂O₃, CeO₂, Ta₂O₅, HfO₂, ZrO₂, TiO₂, HfSiO, HfAIO, ZrSiO, ZrAlO, or AlSiO.

The intermediate film 54c includes, for example, a silicon nitride.

Between the source member SM and the stacked body ML, there is provided an insulating film SMi.

On the insulating section 66L and the stacked body ML, there is provided an insulating film 71. On the insulating film 71, there is provided an insulating film 72. On the insulating film 72, there is provided an insulating film 73. On the insulating film 73, there is provided an insulating film 74. On the insulating film 74, there is provided an insulating film 75.

In the connection regions CR, on the plurality of conductive layers 21, there are respectively provided contact plugs 81. The contact plugs 81 each has, for example, a roughly columnar shape extending in the Z-axis direction. Each of the contact plugs 81 is electrically connected to corresponding one of the plurality of conductive layers 21. The contact plugs 81 each includes a conductive material such as tungsten. On the periphery of each of the contact plugs 81, there is disposed the insulating section 66L.

Between the contact plug 81 and the insulating section 66L and between the contact plug 81 and the conductive layer 21, which is electrically connected to that contact plug 81, there is provided a barrier metal film 81a. The barrier metal films 81a is a film including metal, and includes, for example, titanium. The barrier metal film 81a can also be a film including titanium nitride.

On each of the semiconductor pillars 50, there is provided a plug 82. On the plug 82, there is disposed a plug 83. On the plugs 83, there is disposed a plurality of bit lines 91 extending in, for example, the X-axis direction. The semiconductor pillar 50 and one of the plurality of bit lines 91 are electrically connected to each other via the plugs 82 and 83.

On the source member SM, there is provided a plug 84. On the plug 84, there is disposed a source interconnection 92. The source member SM and the source interconnection 92 are connected to each other via the plug 84.

On the contact plug 81, there is provided a plug 85. On the plug 85, there is provided, for example, an interconnection 93 extending in the X-axis direction. The contact plug 81 and the interconnection 93 are connected to each other via the plug 85.

In the embodiment, the stacked body ML can also be separated from the substrate 10s. It is also possible to provide an interconnection connected to the memory cell MC between the memory cell MC to be connected to the conductive layer included in the stacked body ML and the substrate 10s.

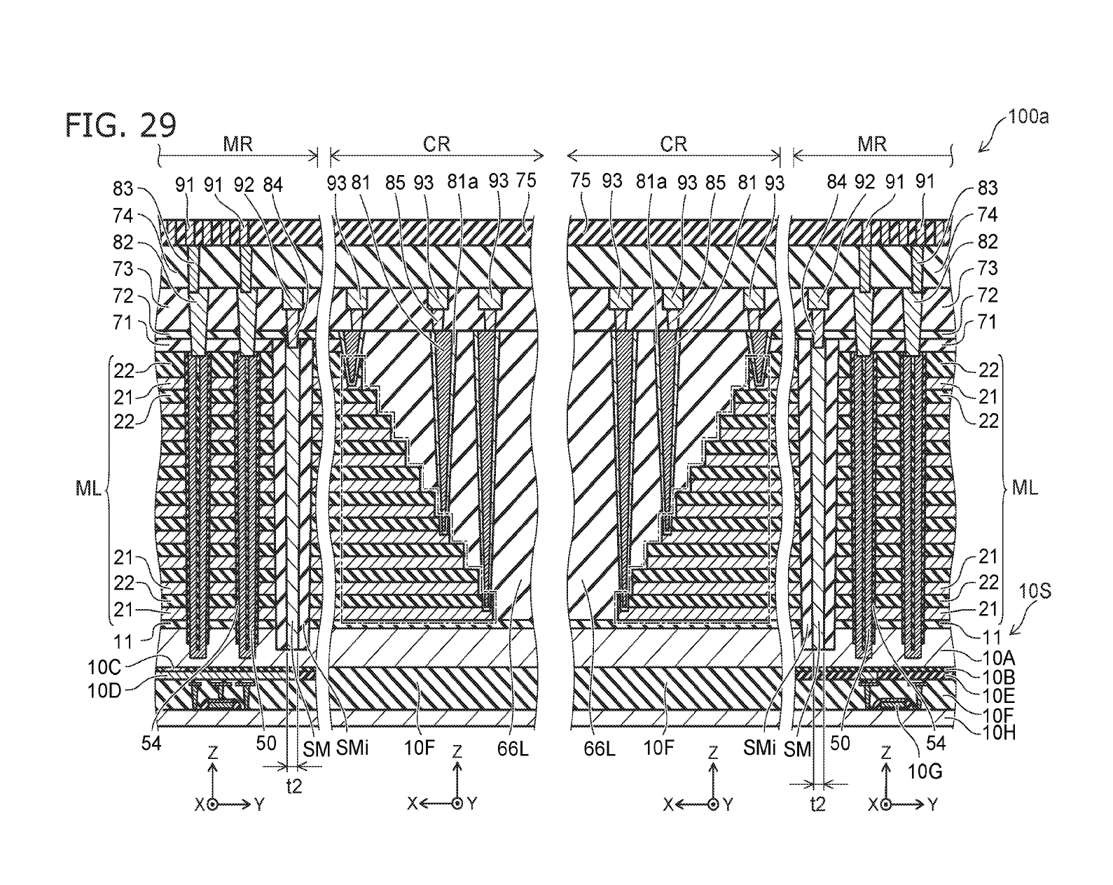

FIG. 29 is a schematic cross-sectional view illustrating a semiconductor memory device according to the embodiment.

As shown in FIG. 29, in another semiconductor memory device 100a according to the embodiment, other layers including transistors 10G are provides instead of the substrate 10s presented in FIG. 27. In the semiconductor memory device 100a, the transistors 10G are provided on a substrate 10H, which is made of silicon, for example. An insulating layer 10F is provided around transistors 10G. Interconnection layer 10D is provided on the insulating layer 10F. Another insulating layer 10E is provided around the interconnection layer 10D. The interconnection layer 10D may functions as a source line, for example. In this example, the interconnection layer 10D is electrically connected with a terminal (source or drain) of the transistor 10G.

A connecting member 10C is provided on the interconnection layer 10D to be electrically connected therewith. Another insulating layer 10B is provided around the connecting member 10C. A conductive layer 10A is provided on the connecting member 10C, on the insulating layer 10B and on the insulating layer 10F. The conductive layer 10A is electrically connected with the interconnection layer 10D via the connecting member 10C.

According to the embodiment, there can be provided a semiconductor memory device capable of increasing the memory capacity, and a method for manufacturing the semiconductor memory device.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor memory devices such as conductive layers, insulating layers, memory cells, semiconductor pillars, memory films, connection sections, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor memory devices, and methods for manufacturing the same practicable by an appropriate design modification by one skilled in the art based on the semiconductor memory devices and methods for manufacturing the same described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor memory device, comprising:
forming a trench in a structure provided on a lower body, the structure including a plurality of first films and a plurality of second films alternately stacked in a first direction crossing a surface of the lower body;
removing a part of the plurality of first films being exposed inside of the trench, one of the plurality of first films having a first side surface crossing a second direction perpendicular to the first direction, other one of the plurality of first films being positioned between the one of the plurality of first films and the lower body, the other one of the plurality of first films having a second side surface crossing the second direction, the removing the part of the plurality of first films making a second distance shorter than a first distance, the first distance being between the trench and the first side surface in the second direction, the second distance being between the trench and the second side surface in the second direction;
filling a first space formed by the removing the part of each of the plurality of first films with an insulating material;
forming a hole in the structure after the filling with the insulating material, and removing the plurality of first films via the hole; and
filling a second space formed by the removing the first films with a conductive material to form a plurality of conductive films arranged in the first direction.

2. The method according to claim 1, further comprising:
forming a third film on a sidewall of the trench between the forming the trench and the removing the part of the plurality of first films; and
making a length along the second direction of the third film at a first position distant from the lower body shorter than a length along the second direction of the third film at a second position between the first position and the lower body between the forming the third film and the removing the part of the plurality of first films,
the removing the part of the plurality of first films including
removing a part of the third film corresponding to the first position, and removing at least a part of one of the plurality of first films exposed by the removing the part corresponding to the first position, and
removing a part of the third film corresponding to the second position, and removing at least a part of another of the plurality of first films exposed by the removing the part corresponding to the second position after the removing the part of the third film corresponding to the first position.

3. The method according to claim 1, further comprising:
forming a third film in the trench between the forming the trench and the removing the part of the plurality of first films,
the removing including
removing a part of the third film to cause the third film to recede along the first direction, and removing at least a part of one of the plurality of first films exposed by the recession of the third film, and
causing the third film to further recede, and removing at least a part of another of the plurality of first films exposed by the further recession of the third film after the recession.

4. The method according to claim 1, further comprising:
removing at least a part of a portion of each of the plurality of second films not sandwiched by the plurality of first films in the first direction between the removing the part of the plurality of first films and the filling the first space with the insulating material,
in the filling the first space with the insulating material, a space formed by the removing the at least the part of the portion not sandwiched being further filled with the insulating material.

5. The method according to claim 4, wherein
the plurality of first films are not provided on the portion of each of the plurality of second films not sandwiched by the first films in the first direction.

6. The method according to claim 1, further comprising:
forming a pillar section piercing the structure in the first direction before the forming the trench,
the trench being separated from the pillar section.

7. The method according to claim 6, further comprising:
removing at least a part of a portion of each of the plurality of second films not sandwiched by the plurality of first films in the first direction between the removing the part of the plurality of first films and the filling the first space with the insulating material,
in the filling the first space with the insulating material, a space formed by the removing the at least the part of the portion not sandwiched being further filled with the insulating material, and
in the removing the part of the plurality of, the plurality of second films being held by the pillar section.

8. The method according to claim 1, wherein
an etching rate of the one of the plurality of first films with respect to an etchant used in the removing the part of the plurality of first films is higher than an etching rate of the other one of the plurality of first films with respect to the etchant.

9. The method according to claim 1, wherein
a density of the one of the plurality of first films is lower than a density of the other one of the plurality of first films.

10. The method according to claim 1, wherein
the one of the plurality of first films has a first peak corresponding to a bond between hydrogen and nitrogen, and a second peak of a bond between silicon and nitrogen in an infrared spectroscopic analysis,
the other one of the plurality of first films has a third peak corresponding to a bond between hydrogen and nitrogen, and a fourth peak corresponding to a bond between silicon and nitrogen in the infrared spectroscopic analysis, and
a ratio of an intensity of the third peak with respect to an intensity of the fourth peak is lower than a ratio of an intensity of the first peak with respect to an intensity of the second peak.

11. The method according to claim 1, wherein
the removing the part of each of the plurality of first films includes removing the part of each of the plurality of first films using wet etching.

12. The method according to claim 1, wherein
the first films include silicon nitride, and
the second films include silicon oxide.

13. The method according to claim 1, further comprising:
forming a memory hole piercing the structure in the first direction before the removing the plurality of first films;
forming a memory film on an inner wall surface of the memory hole; and
forming a semiconductor pillar extending in the first direction in a remaining space of the memory hole after the forming the memory film.

14. A method of manufacturing a semiconductor memory device, comprising:
forming a trench in a structure, which is provided on a lower body, and includes a plurality of first films and a plurality of second films alternately stacked in a first direction crossing a surface of the lower body;
removing a part of the plurality of second films being exposed inside of the trench, one of the plurality of second films having a third side surface crossing a second direction perpendicular to the first direction, other one of the plurality of second films being positioned between the one of the plurality of second films and the lower body, the other one of the plurality of second films having a fourth side surface crossing the second direction, the removing the part of the plurality of second films making a fourth distance shorter than a third distance, the third distance being between the trench and the third side surface in the second direction, the fourth distance being between the trench and the fourth side surface in the second direction;
removing a part of each of the plurality of first films after the removing the part of the plurality of second films, the plurality of second films not being provided on the part of each of the plurality of first films;
filling a first space with an insulating material, the first space being formed by the removing the part of each of the plurality of first films and by the removing the part of each of the plurality of second films;
forming a hole in the structure after the filling the first space with the insulating material, and removing the plurality of first films via the hole; and
filling a second space formed by the removing the plurality of first films with a conductive material to form a plurality of conductive films arranged in the first direction.

15. The method according to claim 14, further comprising:
forming a third film on a sidewall of the trench between the forming the trench and the removing the part of the plurality of second films; and
making a length along the second direction of the third film at a first position distant from the lower body shorter than a length along the second direction of the third film at a second position located between the first position and the lower body between the forming the third film and the removing the part of the plurality of second films,
the removing the part of the plurality of second films including
removing a portion of the third film corresponding to the first position, and removing at least a part of one of the plurality of second films exposed by the removing the portion corresponding to the first position, and
removing a portion of the third film corresponding to the second position, and removing at least a part of another of the plurality of second films exposed by the removing the portion corresponding to the second position after the removing the portion of the third film corresponding to the first position.

16. The method according to claim 14, further comprising:
forming a third film in the trench between the forming the trench and the removing the part of the plurality of second films,
the removing the part of the plurality of second films including
removing a part of the third film to cause the third film to recede along the first direction, and removing at least a part of one of the plurality of second films exposed by the recession of the third film, and
causing the third film to further recede, and removing at least a part of another of the plurality of second films exposed by the further recession of the third film after the recession.

17. The method according to claim 14, further comprising:
forming a pillar section piercing the structure in the first direction before the forming the trench,
the trench being separated from the pillar section.

18. The method according to claim 1, wherein
the plurality of second films include silicon oxide, and
a carbon concentration of the one of the plurality of second films is lower than a carbon concentration of the other one of the plurality of second films.

19. The method according to claim 15, further comprising:
forming a memory hole piercing the structure in the first direction before the removing the plurality of second films;
forming a memory film on an inner wall surface of the memory hole; and
forming a semiconductor pillar extending in the first direction in a remaining space of the memory hole after the forming the memory film.

20. A semiconductor memory device comprising:
a stacked body including
a first insulating layer,
a second insulating layer separated from the first insulating layer in a first direction, and
a first conductive layer provided between the first insulating layer and the second insulating layer;
a semiconductor pillar extending in the first direction through the stacked body; and
a memory film provided between the semiconductor pillar and the stacked body,
the first conductive layer including an end surface separated from the memory film in a second direction crossing the first direction, the end surface crossing the second direction,
the end surface including first through third regions,
a position in the first direction of the first region being located between a position in the first direction of the third region and a position in the first direction of the first insulating layer,
a position in the first direction of the second region being located between the position in the first direction of the third region and a position in the first direction of the second insulating layer, and
a third distance along the second direction between the third region and the memory film being shorter than a first distance along the second direction between the first region and the memory film.
